(19) United States
(12) Patent Application Publication
(10) Pub. No.: US 2013/0173189 A1
(43) Pub. Date: Jul. 4, 2013

(54) ROBUST HIGH RESOLUTION SPECTRUM ESTIMATION METHOD FOR ACCURATE PHASOR, HARMONIC AND INTERHARMONIC MEASUREMENT IN POWER SYSTEMS

(71) Applicants: Peng Zhang, Storrs, CT (US); Hui Xue, Beijing (CN); Ali Abdollahi, Storrs, CT (US)

(72) Inventors: Peng Zhang, Storrs, CT (US); Hui Xue, Beijing (CN); Ali Abdollahi, Storrs, CT (US)

(73) Assignee: University of Connecticut, a public institution of higher education, Farmington, CT (US)

(21) Appl. No.: 13/730,421

(22) Filed: Dec. 28, 2012

Related U.S. Application Data
(60) Provisional application No. 61/581,535, filed on Dec. 29, 2011.

(51) Int. Cl. G06F 17/17; G06F 17/16; G01R 21/00

(52) U.S. Cl. CPC G06F 17/17; G01R 21/00; G06F 17/16
USPC 702/60

(57) ABSTRACT

A high-resolution Subspace-Least Mean Square (S-LMS) method for harmonic and interharmonic measurement in power systems is provided. The eigenvector corresponding to the smallest eigenvalue is used to calculate the frequencies of the signal, and the least mean square method is used to estimate the amplitude and phase angle of harmonic and interharmonic components based on the computed frequencies and time domain measurements of the signal. Three schemes, namely sparsity, catch-and-pinpoint, and hybrid are presented. The S-LMS method provides accurate phasor, harmonic and interharmonic measurements for power system monitoring. The speed, accuracy, and resilience of the S-LMS method can be further increased by each of the three schemes. The method has a wide range of applications in power quality analyzers, synchronized phasor measurement, situational awareness, dynamic equivalencing, and smart meters.

### CROSS-REFERENCE TO RELATED APPLICATIONS

This application claims the benefit of U.S. Provisional Application No. 61/581,535, filed on Dec. 29, 2011, the entire contents of which are incorporated by reference herein.

### STATEMENT REGARDING FEDERALLY SPONSORED RESEARCH

This invention was made with government support under Contract No. DE-EE0003226, awarded by the Golden Field Office, U.S. Department of Energy. The government has certain rights in the invention.

### BACKGROUND OF THE DISCLOSURE

1. Field of Disclosure

A method is disclosed for harmonic and interharmonic measurement in power systems using a high-resolution Subspace-Least Mean Square (S-LMS) method. The method provides higher frequency resolution, enhanced noise tolerance, and improved performance under fundamental frequency deviations as compared with present methods. The speed, accuracy, and resilience of the S-LMS method can be further increased by three schemes. The S-LMS method of the present disclosure may be used for applications such as power quality analyzers, synchronized phasor measurement, dynamic equivalencing, and smart meters.

2. Description of Related Art

The increasing uses of renewable energy resources and of power electronic devices have resulted in severe harmonic and interharmonic distortions in power system signals. Modern power electronic converters generate a wide spectrum of harmonics and interharmonics. Accurate measurement of harmonics and interharmonics are of fundamental importance for power quality issues and power system health, and functions as the basis for harmonic/interharmonic mitigation measures and devices.

At least two methods are used currently to measure power system harmonics and interharmonics. Discrete Fourier transform (DFT) is a widely-used tool for analyzing harmonics. DFT assumes that only harmonics are present in power system signals, and that periodicity intervals are fixed. However, in real-world power systems, interharmonics often exist with time-varying or long periodicity intervals. Thus, DFT suffers from significant leakage and picket fence effects, and also the significant problem of resolution because of several invalid assumptions made in this method, such as zero data or repetitive data outside of the duration of observations. DFT is able to accurately capture harmonics under synchronous sampling situations. However, if both interharmonic and harmonic components exist in the test signal, or during serious dynamic events (e.g., loss of synchronism and slow oscillation), measurement accuracy of DFT is inevitably lower than in the steady state without harmonic or off-harmonic disturbances.

A second method that is currently used to measure power system harmonics and interharmonics is windowed DFT, which was developed to reduce the spectral leakage and picket fence effects found with conventional DFT, in order to improve measurement precision. However, a disadvantage of windowed DFT is that frequency resolution is decreased compared to conventional DFT, meaning a longer data window is required. This makes windowed DFT unsuitable for measuring interharmonics which are usually unstable and time-varying.

### SUMMARY OF THE DISCLOSURE

The present disclosure provides a high resolution Subspace-Least Mean Square (S-LMS) method for harmonic and interharmonic measurement in power systems. The S-LMS method is robust and accurate, and provides higher frequency resolution, enhanced tolerance of noise, and better performance under fundamental frequency deviations as compared with the conventional methods described above.

The S-LMS method combines the strengths of the Subspace concept and the Least Mean Square approach for harmonic and interharmonic measurement, providing accurate estimations of any harmonics and interharmonics even in noisy environments and/or fast dynamic conditions with a data sampling window of only 33.3 milliseconds (ms). The S-LMS method thereby provides fast and highly accurate phasor, harmonic, and interharmonic measurements for power system monitoring and control.

The speed of the S-LMS method can be further increased by each of three schemes: (1) a “sparsity” (or “heuristic”) scheme that permits a sparse number of candidate frequencies to be scanned to reduce searching loads; (2) a “catch-and-pinpoint” scheme that employs an iterative multisectional search approach to accelerate location of harmonics and interharmonics; and (3) a “hybrid” scheme that combines the “sparsity” and “catch-and-pinpoint” schemes to achieve still greater increases in speed as compared with the original S-LMS method. By using both the real-valued and imaginary-valued components of the signal, each of the schemes (heuristic—Heu, catch-and-pinpoint—CP, and hybrid—Hyb) increases or improves the speed, accuracy, resiliency, and robustness of the S-LMS method.

Signal vectors and noise vectors are, in general, complex-valued. By adopting only the real-valued component of these complex vectors, each of the above schemes can have a corresponding real-implemented version (i.e., HeuR, CPR, and HybR) that further increases speed and accuracy of the method as compared with the original S-LMS method.

Thus, including the three “real-implemented” versions, the present disclosure provides a total of six different schemes to improve the speed, accuracy, resiliency, and robustness of the S-LMS method.

The sparsity, catch-and-pinpoint, and hybrid schemes can also improve the accuracy of harmonics measurements for high-voltage (HV) power systems where interharmonics are often negligible. By using the sparsity of power system signals, these schemes are not only faster but also more accurate and more robust as compared with the original S-LMS method.

### BRIEF DESCRIPTION OF THE DRAWINGS

FIG. 1, subparts (a) and (b), illustrates an exemplary embodiment of a zero-finding method for subspace function H(ω) of the present disclosure for a signal with a single frequency x(n)=cos(2πf₁t), where f₁=60 Hz. Specifically, FIG. 1(a) illustrates waveforms of H(ω) for a noise-free x(n), and FIG. 1(b) illustrates the H(ω) curve under a 60 dB signal-to-noise ratio (SNR).

FIG. 2, subparts (a) and (b), are magnified views of the waveforms in FIGS. 1(a) and 1(b), respectively, of the portion of the x-axis between 0 and 100 Hz and of the y-axis between 0 and 1.

FIG. 3, subparts (a) and (b), illustrates another exemplary embodiment of a zero-finding method of subspace function H(ω) of the present disclosure for a signal with multiple frequencies x(n)=cos(2πf₁t)+0.1 cos(2πf₂t)+0.01 cos(2πf₃t)+0.01 cos(2πf₄t), where f₁=60 Hz, f₂=128 Hz, f₃=288 Hz, and f₄=360 Hz. FIG. 3(a) illustrates waveforms of H(ω) for a noise-free x(n), and FIG. 3(b) illustrates H(ω) for x(n) with SNR=60 dB.

FIG. 4, subparts (a) and (b), are magnified views of the waveforms in FIGS. 3(a) and 3(b), respectively, of the portion of the x-axis between 0 and 600 Hz and of the y-axis between 0 and 1.

FIG. 5, subparts (a) and (b), illustrates the spectra obtained by conventional Discrete Fourier transform (DFT) methods and by an exemplary embodiment of the Subspace-Least Mean Square (S-LMS) method of the present disclosure, respectively, for high frequency resolution.

FIG. 6(a) is a magnified view of a portion of the DFT spectrum in FIG. 5(a) from 0 to 600 Hz, and FIG. 6(b) is a magnified view of the S-LMS spectrum in FIG. 5(b) from 0 to 600 Hz.

FIG. 7 illustrates the H(ω) waveform for the frequency resolution example in FIGS. 5(a) and (b).

FIG. 8 is a magnified view of a portion of the H(ω) waveform in FIG. 7 from 0 to 600 Hz.

FIG. 9, subparts (a) and (b), illustrates the spectra obtained by DFT and by S-LMS, respectively, for ultra-high frequency resolution where the test signal carries two components with a frequency difference Δf=0.2 Hz.

FIG. 10(a) is a magnified view of a portion of the DFT spectrum in FIG. 9(a) from 0 to 100 Hz, and FIG. 10(b) is a magnified view of the S-LMS spectrum in FIG. 9(b) from 0 to 100 Hz.

FIG. 11 is a magnified view of a portion of the H(ω) waveform for the embodiment illustrated in FIG. 9.

FIG. 12, subparts (a) and (b), illustrates the spectra obtained by DFT and by S-LMS, respectively, for a signal including white noise with SNR=50 dB.

FIG. 13(a) is a magnified view of a portion of the DFT spectrum in FIG. 12(a) from 0 to 600 Hz, and FIG. 13(b) is a magnified view of the S-LMS spectrum in FIG. 12(b) from 0 to 600 Hz.

FIG. 14, subparts (a) and (b), illustrates the spectra obtained by DFT and by S-LMS, respectively, for a signal having SNR=40 dB.

FIG. 15, subparts (a) and (b), illustrates the spectra obtained by DFT and by S-LMS, respectively, for a signal having a fundamental frequency deviation of 0.1 Hz and a 9^{th} harmonic frequency deviation of 0.9 Hz.

FIG. 16, subparts (a) and (b), illustrates the spectra obtained by DFT and by S-LMS, respectively, for fundamental frequency deviation up to 20 HZ and a 9^{th} harmonic frequency deviation up to 180 Hz.

FIG. 17(a) is a magnified view of a portion of the DFT spectrum in FIG. 16(a) from 0 to 600 Hz, and FIG. 17(b) is a magnified view of the S-LMS spectrum in FIG. 16(b) from 0 to 600 Hz.

FIG. 18 illustrates a real-world power system signal recorded from a factory with VFD motors that is shown as a recorded voltage waveform over a data window length of 1/30 seconds.

FIG. 19, subparts (a) and (b), illustrates the spectra obtained by DFT and by S-LMS, respectively, for the recorded voltage waveform in FIG. 18.

FIG. 20(a) is a magnified view of a portion of the DFT spectrum in FIG. 19(a) from 0 to 1900 Hz, and FIG. 20(b) is a magnified view of the S-LMS spectrum in FIG. 19(b) from 0 to 1900 Hz.

FIG. 21 illustrates a real-world power system signal recorded from a factory with VFD motors that is shown as a recorded voltage waveform over a data window length extended to 1/20 seconds.

FIG. 22, subparts (a) and (b), illustrates the spectra obtained by DFT and by S-LMS, respectively, for the recorded voltage waveform in FIG. 21.

FIG. 23(a) is a magnified view of a portion of the DFT spectrum in FIG. 22(a) from 0 to 1900 Hz, and FIG. 23(b) is a magnified view of the S-LMS spectrum in FIG. 22(b) from 0 to 1900 Hz.

FIG. 24(a) illustrates the original S-LMS method with all frequencies from zero to Nyquist frequency scanned as candidate frequencies, and FIG. 24(b) illustrates the enhanced method applying the sparsity scheme, in which a full scan is performed only around the nominal frequency.

FIG. 25 illustrates the subspace function around the nominal frequency and the 5^{th} harmonic and 7^{th} harmonic, respectively, for the signal: x(t)=cos(2π60t)+0.05 cos(2π300t+30°)+0.02 cos(2π420t+25°), showing the subspace function for a noise-free signal (solid line) and a noisy signal with SNR=50 dB (dotted line).

FIG. 26 is a flow chart of an embodiment of the catch-and-pinpoint scheme of the present disclosure.

FIG. 27 illustrates the subspace function of an embodiment of the catch-and-pinpoint scheme in the first iteration for an estimate of existing frequencies, with local minima at 60 Hz, 250 Hz, and 455 Hz.

FIG. 28 illustrates the subspace function of the catch-and-pinpoint scheme in the second iteration, around the detected frequencies from the first iteration in FIG. 27.

FIG. 29 illustrates the subspace function of the catch-and-pinpoint scheme in the third iteration, around the detected frequencies from the second iteration in FIG. 28.

FIG. 30 illustrates the subspace function of the catch-and-pinpoint scheme in the fourth iteration, around the detected frequencies from the third iteration in FIG. 29.

FIG. 31 illustrates a comparison of the mean processing time for embodiments of different schemes of the present disclosure, in milliseconds (ms) and cycles (cl), namely, the heuristic (Heu), catch-and-pinpoint (CP), and hybrid (Hyb) schemes, as well as their real counterparts (HR, CPR, and HybR, respectively) with real-valued construction of the subspace function, as compared against the original S-LMS method (not shown in FIG. 31) that consumes 371 ms or 22.24 cl.

FIG. 32 illustrates the ratio of speed enhancement of each of the different schemes in FIG. 31 compared to the original S-LMS algorithm.

FIG. 33 illustrates the dynamic behavior of estimation (step change response) showing the true frequency (solid line) and estimated frequencies using the Hyb (dot-dash line) and HybR (dotted line) schemes, with the time shown in cycles.

FIG. 34 illustrates the dynamic behavior of estimation (ramp response) showing the true frequency (solid line) and estimated frequencies using the Hyb (dot-dash line) and HybR (dotted line) schemes, with the estimated signal shown with one cycle shift to the left.

FIG. 35 illustrates the dynamic behavior of estimation (modulated frequency response) showing the true frequency (solid line) and estimated frequencies using the Hyb (dot-dash line) and HybR (dotted line) schemes, with the estimated signal shown with one cycle shift to the left, for a test signal f=60+sin(2π6t)+0.5 sin(2π1t).

FIG. 36 illustrates the recorded voltage signal (“true”), as compared with reconstructed signals using the catch-and-pinpoint schemes and the original method (dotted line “CP and Org”).

FIG. 37 illustrates the result of a test case comparing HybR with two other methods (Prony and Discrete Fourier Transform) where f_{fund} is 59.9 Hz and the signal is slightly noisy with an SNR of 80 dB.

### DETAILED DESCRIPTION OF THE DISCLOSURE

The present disclosure provides a high-resolution method for harmonic and interharmonic measurement in power systems based on a “Subspace-Least Mean Square” (S-LMS) method, which is a combination of Subspace (S) and Least Mean Square (LMS) methods.

The S-LMS method of the present disclosure provides accurate estimates of any harmonics and interharmonics, even in noisy environments and/or fast dynamic conditions with a data sampling window of only 33.3 milliseconds (ms).

The S-LMS method is able to directly estimate phasors, including frequency, magnitude and phase angles for power system states containing harmonics, interharmonics, and noise.

Power system signals are non-stationary and nonlinear, because power systems are nonlinear, and thus, power electronic controls are nonlinear as well. The S-LMS method of the present disclosure can provide ultra-high resolution phasor estimation for any power system signals. In addition, the S-LMS method is able to deal with nonlinear signals with noises, and thus is a unique and excellent method for directly measuring not only power system signals, but also any sinusoidal signals.

Thus, the S-LMS method provides fast and highly accurate phasor, harmonic, and interharmonic measurements for power system monitoring and real-time control.

The present disclosure further provides three schemes by which the speed of the S-LMS method can be further increased: (1) a “sparsity” scheme that permits a sparse number of candidate frequencies to be scanned to reduce searching loads; (2) a “catch-and-pinpoint” scheme that employs an iterative multisectional search approach to accelerate location of harmonics and interharmonics; and (3) a “hybrid” scheme that combines the “sparsity” and “catch-and-pinpoint” schemes to achieve still greater increases in speed as compared with the original S-LMS method. The sparsity, catch-and-pinpoint, and hybrid schemes can also improve the accuracy of harmonics measurements for high-voltage (HV) power systems where interharmonics are often negligible. By using the sparsity of power system signals, these schemes are not only faster but also more accurate and more robust as compared with the original S-LMS method. These enhanced schemes are disclosed below.

The present method also uses Subspace methods to measure power system frequencies. As used herein, “Subspace” methods use stochastic signals modeled by a sum of random sinusoidal signals in background noise with known covariance function. The zeros of the z transform of the eigenvector corresponding to the minimum eigenvalue of the covariance matrix lie on the unit circle, and the frequencies of the sinusoids can be extracted from angular positions of the zeros. The eigenvectors can be divided into two orthogonal groups: eigenvectors spanning the signal space and those spanning the noise space. The eigenvectors spanning the noise space are the one whose eigenvalues are the smallest. A major advantage of Subspace methods is high frequency resolution which is independent of data window length.

“Least Mean Square” (LMS) methods, as used herein, mean the approximate solution of overdetermined systems; i.e., sets of equations for which there are more equations than unknowns. “Least squares” means that the overall solution minimizes the sum of the squares of the errors made in solving every single equation. Least Mean Square methods provide an elegant and powerful approach for signal processing in time-domain, and can provide the solution for overdefined equation sets when more measurements than states are represented in the estimation problems. Among the benefits of LMS is its increased immunity to noise, as well as its numerical robustness.

The frequencies of the signal can be obtained by searching the zeros of a frequency function which is constructed using the eigenvector corresponding to the smallest eigenvalue of autocorrelation matrix.

A least mean square (LMS) approach is used to calculate amplitudes and phase angles of harmonic and interharmonic components, based on the computed frequencies and time domain measurements of the signal.

The S-LMS method provides ultra-high frequency resolution, e.g., 0.2 Hz for a data window length of 1/30 seconds, which cannot be obtained by any conventional method for harmonic and interharmonic measurement currently used for power systems.

Also, different than other subspace methods, the present S-LMS method does not require counting the number of sinusoids in the test signal for computation of the spectrum. This not only reduces computation burden but also increases accuracy.

In addition, the eigenvector corresponding to the smallest eigenvalue of autocorrelation matrix, namely minimum eigenvector, are used to obtain frequencies. Unlike Pisarenko's method, which also uses the minimum eigenvector, for the present method, the length of the minimum eigenvector can be an arbitrary number larger than the number of the sinusoids. This eliminates the need to estimate the number of the sinusoidals, and also implies better noise resistance of S-LMS method than Pisarenko's method because more information can be used to estimate frequencies.

Further, Subspace and Least Mean Square methods are combined to obtain accurate harmonic and interharmonic measurement. Although there may be some spurious values in frequency measurement, these spurious values can be treated as noise because they will have very low amplitude after LMS calculations.

The present S-LMS method performs well in a very low SNR environment. It is difficult for other subspace methods to estimate the number of sinusoids (harmonics or interharmonics) under low SNR conditions. The present S-LMS method avoids the estimation of the number of sinusoids. Therefore, the S-LMS method of the present disclosure provides highly stable performance even in very noisy environments.

The S-LMS method of the present disclosure provides accurate phasor, harmonic, and interharmonic measurements for power system monitoring. The method has applications including power quality analyzers, synchronized phasor measurement, situational awareness, dynamic equivalencing, and smart meters.

As a parameter estimation method for sinusoidal models, the S-LMS method of the present disclosure has other applications in analyzing, modeling and manipulating time-series such as speech and audio signals, and radar and sonar signals. For instance, the S-LMS method can be used to estimate delay and Doppler profiles from Frequency Modulated Continuous Wave (FMCW) channel data with in-band interference, to analyze interharmonics in electric power systems and submarine systems, and to estimate sinusoidal parameters for speech sinusoidal models. The method can also be directly applied to parameter estimation of sinusoidal FM signals for radar systems, multi-path communication channels, helicopter recognition, and sonar.

An exemplary embodiment of the present disclosure provides a power system signal x(n) that consists of L spectral components and additive white Gaussian noise (AWGN) w(n) according to equation (1):

$$x ( n ) = {\sum }_{i = 1}^{L} {A}_{i} {e}^{j n {ω}_{i}} + w ( n ) \qquad ( 1 )$$

where Aᵢ=|Aᵢ|e^{jφ}^{ᵢ}, |Aᵢ| is the amplitude, φᵢ is the phase angle of the corresponding component, and ωᵢ is the frequency of i^{th} component.

The autocorrelation matrix of x(n), Rₓ, is an N-by-N Hermitian matrix; i.e., Rₓ=Rₓ^{H}, where the symbol H indicates the conjugate transpose of a matrix. Rₓ can be expressed in terms of its eigendecomposition, in equation (2):

$${R}_{x} = V Λ {V}^{H} = {\sum }_{i = 1}^{N} {λ}_{i} {v}_{i} {v}_{i}^{H} \qquad ( 2 )$$

where Λ=diag(λ₁, λ₂, . . . λₙ) contains the eigenvalues of Rₓ in descending order, V=[v₁, v₂, . . . v_{N}] is the matrix of corresponding eigenvectors. The matrix V can be split into two matrices: the N×L matrix of signal eigenvectors V_{S}=[v₁, v₂, . . . v_{L}] and N×(N−L) matrix of noise eigenvectors Vₙ=[v_{L+1}, v_{L+2}, . . . v_{N}].

Obviously, the eigenvector vₙ corresponding to the smallest eigenvalues must be a noise eigenvector and is orthogonal to the signal subspace, or v_{N}⊥V_{S}. The following equation (3), therefore, can be obtained:

v_{N}^{T}Vₛ=0 (3)

The signal subspace can be spanned, as in equation (4):

Vₛ=[e₁,e₂, . . . e_{L}] (4)

where eᵢ=[1 e^{jω}^{ᵢ} . . . e^{j(N-1)ω}^{ᵢ}]^{T}, i=1, 2, . . . L, ωᵢ corresponds to the frequencies in equation (1), and symbol T denotes the transpose of a matrix. Thus, by substituting equation (4) into equation (3), the following relation can be obtained as equation (5):

$${\sum }_{k = 0}^{N - 1} {v}_{N} ( k ) {e}^{j {kω}_{i}} = 0 \qquad ( 5 )$$

A generalized subspace function (6) can then be constructed, with the left-hand side of equation (5) denoted as H(ω):

$$H ( ω ) = {\sum }_{k = 0}^{N - 1} {v}_{N} ( k ) {e}^{j k ω} \qquad ( 6 )$$

Equations (5) and (6) show that, if ωᵢ is a frequency of the signal, then H(ω)=0. Therefore, the frequencies of the signal can be obtained by searching the zeros of H(ω).

To locate the zeros of H(ω), equation (6) can be implemented using the discretized form as equation (7):

H(ω)=H(mΔω)=E₁ν_{N} (7)

where

$${E}_{1} = [ \begin{matrix}1 & 1 & … & 1 \\ 1 & {e}^{j Δ ω} & … & {e}^{j ( N - 1 ) Δ ω} \\ ⋮ & ⋮ & … & ⋮ \\ 1 & {e}^{j m Δ ω} & … & {e}^{j m ( N - 1 ) Δ ω} \\ ⋮ & ⋮ & … & ⋮ \\ 1 & {e}^{j ( 2 π - Δ ω )} & … & {e}^{j ( N - 1 ) ( 2 π - Δ ω )}\end{matrix} ] ,$$

The Δω is the step size in screening signal frequencies, which may be adjusted adaptively. The dimension of E₁ is inversely proportional to Δω. Therefore, if the value of Δω is too small, the computation burden of the present method will be heavy. Otherwise, if Δω is too large, the precision of results will be compromised.

To fulfill the combined requirements for accuracy and computation burden, a Δω=2π×0.1/fₛ (rad) is set, where fₛ is the sampling rate.

After all frequency values are obtained, a matrix E₂ can be constructed, shown as (8):

$${E}_{2} = [ \begin{matrix}1 & 1 & … & 1 \\ {e}^{j {ω}_{1}} & {e}^{j {ω}_{2}} & … & {e}^{j {ω}_{L}} \\ ⋮ & & & \\ {e}^{j M {ω}_{1}} & {e}^{j M {ω}_{2}} & … & {e}^{j M {ω}_{L}}\end{matrix} ] \qquad ( 8 )$$

where M can be any value that is larger than L. Where Y is a column vector of signal measurements Y=[x(1), x(2), . . . , x(M+1)]^{T}, then the following relationship (9) holds:

E₂A=Y (9)

where A=[A₁, A₂, . . . , A_{L}]^{T} and Aᵢ=|Aᵢ|e^{jφ}^{ᵢ}, as in equation (1).

Matrix A carries the information of amplitudes and phase angles of all harmonic/interharmonic components, including fundamental frequency component. To compute A, the least mean square (LMS) method is used to give the results in equation (10):

A=(E₂^{H}E₂)⁻¹E₂^{H}Y (10)

### Implementing the S-LMS Method

As disclosed above, frequencies of the signal are obtained by searching the roots for H(ω)=0. However, through these experiments, it was noticed that due to the existence of noise, the zeros points of H(ω) may be lifted to some small values slightly above zero. Therefore, locating the zeros of H(ω) can be realized by searching the minimum peaks of H(ω) below a threshold h, as follows.

Assume that H(ωᵢ+Δω) and H(ωᵢ−Δω) are the consecutive forward and backward values of H(ωᵢ), respectively. If H(ωᵢ)<h and H(ωᵢ)<H(ωᵢ±Δω), then H(ωᵢ) is treated as zero and ωᵢ is picked as one of the frequencies of the harmonic/interharmonic components of the signal. Otherwise, H(ωᵢ) is treated as non-zero or H(ωᵢ)≠0, and hence ωᵢ is not a frequency of any signal components.

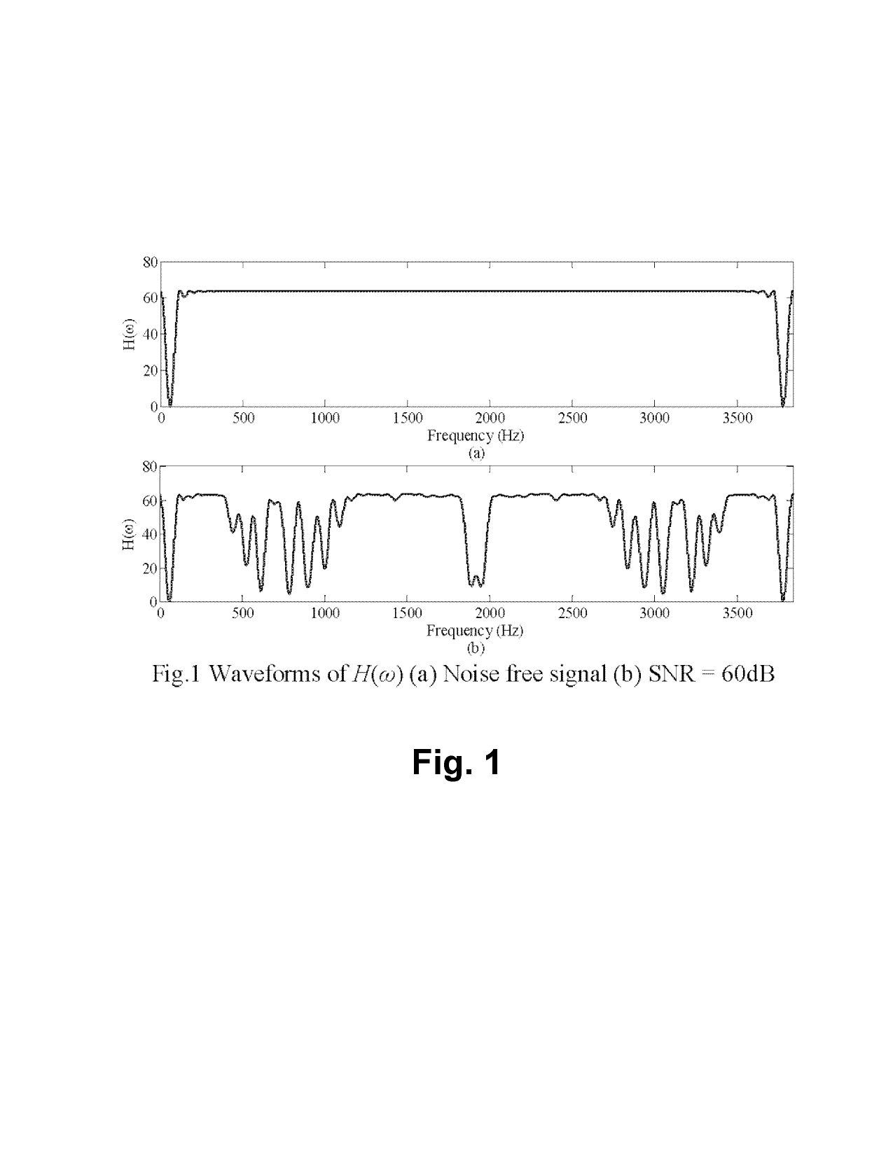

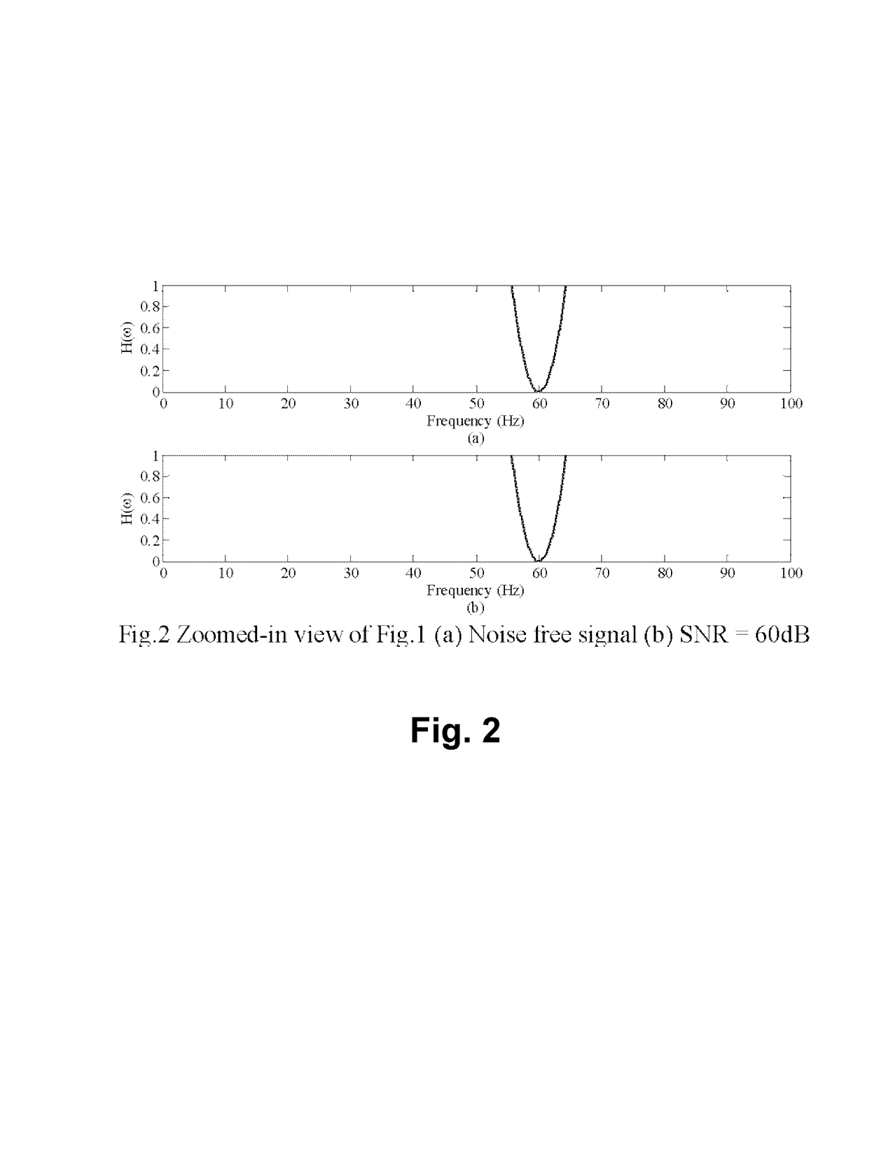

Referring now to the drawings, particularly FIGS. 1 and 2, two examples are given to illustrate and validate the zero-finding method for H(ω).

The first example uses a signal with a single frequency x(n)=cos(2πf₁t), where f₁=60 Hz. The waveforms of H(ω) for this case are computed and shown in FIG. 1, where FIG. 1(a) is H(ω) for a noise-free x(n), and FIG. 1(b) is the H(ω) curve under 60 dB signal-to-noise ratio (SNR).

FIG. 2(a) is a magnified view of FIG. 1(a) and FIG. 2(b) is a magnified view of FIG. 1(b) in the area where the x-axis is between 0 and 100 Hz and y-axis is from 0 to 1. FIGS. 1 and 2 clearly show that the frequency of the signal (60 Hz) can be found by searching H(ω)=0. Notice there can be some frequencies, or spurious frequencies, other than the real frequency of the signal that lead to H(ω)=0, as shown in FIG. 1 and FIG. 2. There are two potential sources that could cause these spurious frequencies. One comes from the frequency function H(ω). Since H(ω) is a N order function, there can be at most N roots for H(ω)=0. This means that there can be at most N frequency values obtained by searching H(ω)=0, among which are some spurious frequency. Another comes from the adding of noise, noise will affect the waveform of H(ω), and gives forth to some spurious peaks, as shown in FIG. 2. However, none of these sources will affect the performance of the S-LMS method because the amplitudes associated with those spurious frequencies will be negligibly low after the LMS calculations. They will be effectively treated as noises in the spectrum. FIG. 1 and FIG. 2 also show that adding 60 dB noise does not affect the accuracy of results.

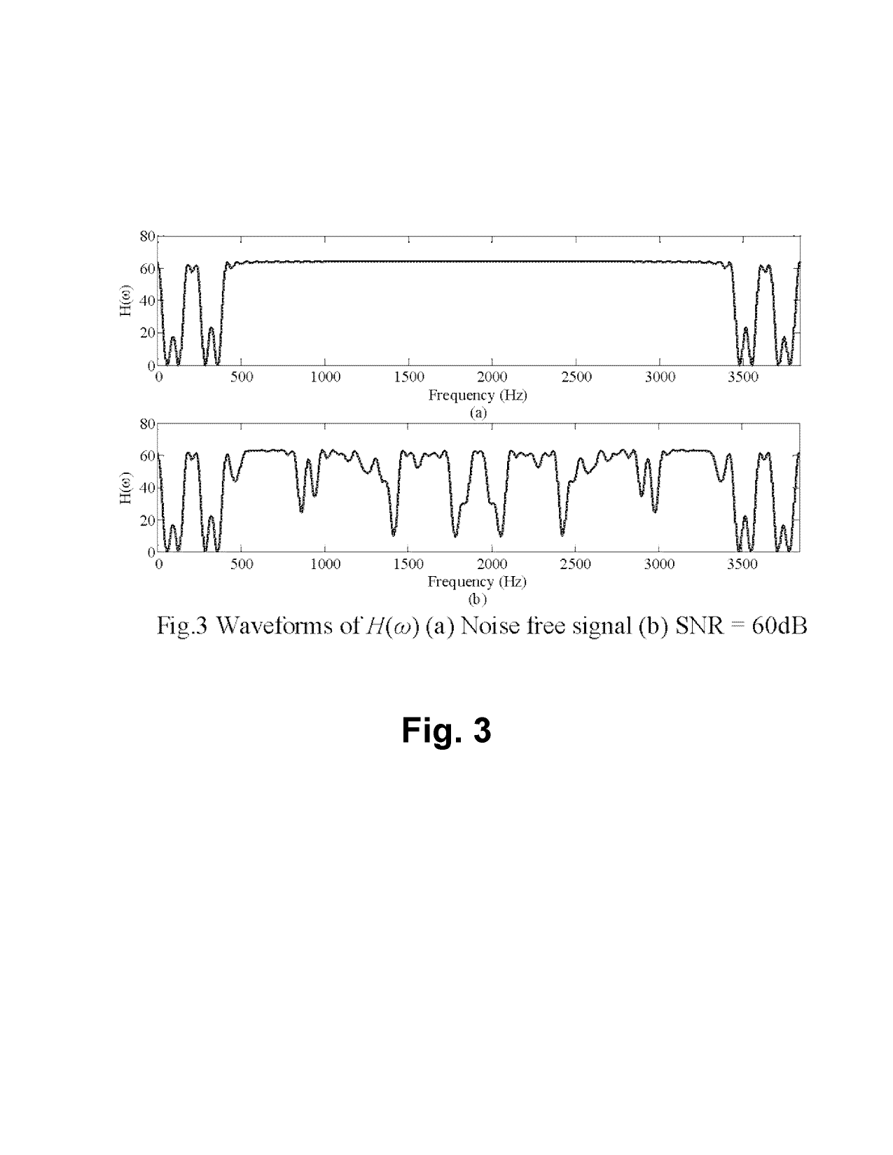

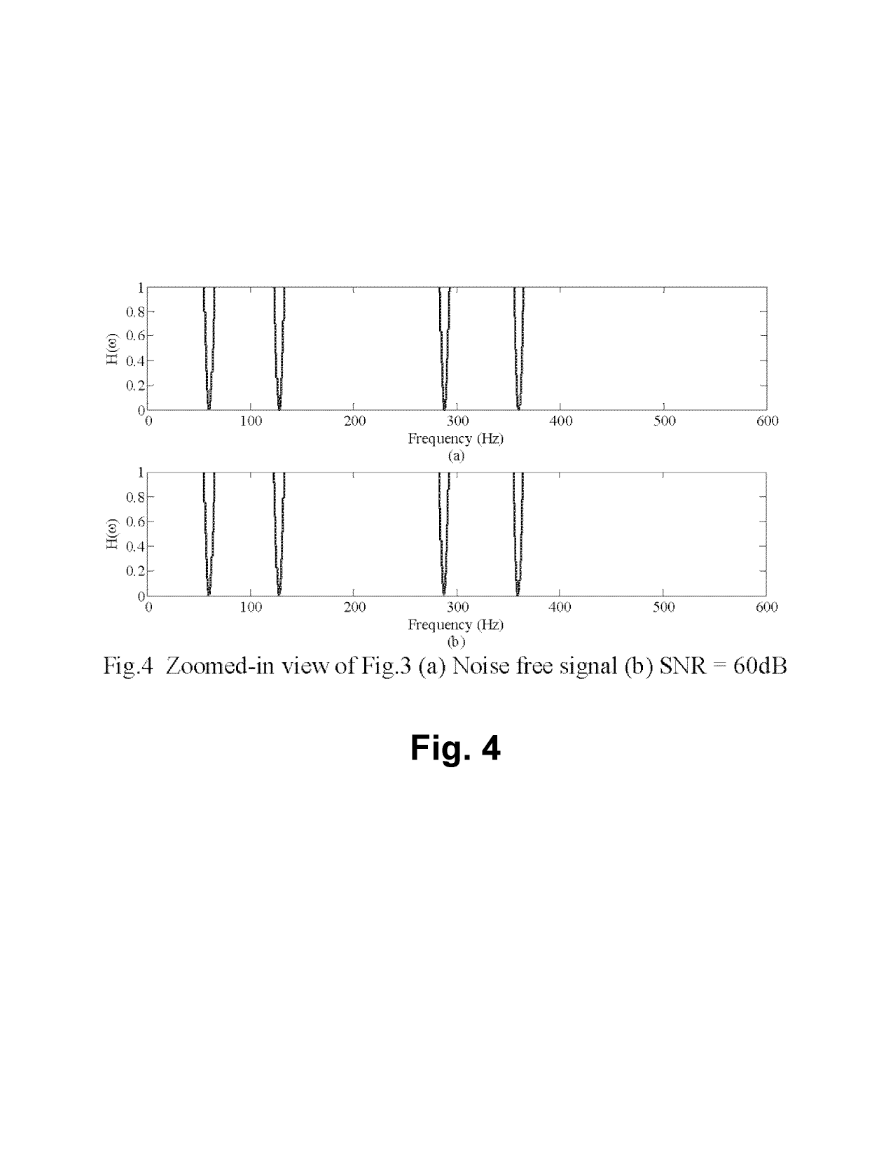

The second example is a signal with multiple frequencies x(n)=cos(2πf₁t)+0.1 cos(2πf₂t)+0.01 cos(2πf₃t)+0.01 cos(2πf₄t), where f₁=60 Hz, f₂=128 Hz, f₃=288 Hz, and f₄=360 Hz. The waveform of H(ω) in this case is shown in FIG. 3, where FIG. 3(a) is H(ω) for a noise-free x(n), and FIG. 3(b) is H(ω) for x(n) with SNR=60 dB.

FIG. 4(a) is a magnified view of FIG. 3(a), and FIG. 4(b) is a magnified view of FIG. 3(b) in the area where the x-axis is from 0 to 600 Hz and y-axis is from 0 to 1. It can also be seen in FIGS. 3 and 4 that all frequencies in x(n) are found by H(ω)=0. The adding of harmonics and interharmonics does not affect the accuracy and correctness of the results. Similar to the first example, spurious peaks are introduced in H(ω), as illustrated in FIGS. 3(b) and 4(b). An observation is that the real peaks are lifted to some small values slightly above zero due to the existence of harmonics and interharmonics in the signal. Therefore, in order to obtain accurate frequency measurements, the minimum points of H(ω) need to be searched under a threshold of h instead of searching H(ω)=0. For the purposes of harmonic and interharmonic measurement, a setting of h=1 can guarantee successful localization of frequencies in the signal, based on numerical experiments.

S-LMS can be adjusted to various sample frequencies and data window lengths. A sample frequency is chosen as 3840 Hz and a data window length as 1/30 s. The reasons are as follows: According to the Nyquist Theorem, the sampling frequency should be at least twice the highest frequency of interest. Information in high frequency components will be missing if sampling frequency is too low, whereas very high sampling frequency will dramatically increase the complexity in hardware and software implementations for S-LMS. Given a nominal frequency of 60 Hz, a sampling frequency of 3840 Hz is selected in this example so that the components within a frequency range of 0 to 1920 Hz can be captured, meaning phasors and higher frequency components up to 31^{st} harmonics and corresponding interharmonics can be accurately estimated. With such sampling frequencies, the experimental data show that:
(a) When SNR decreases to 40 dB, S-LMS with a data window length of 1/30 seconds still guarantees an accurate measurement of all harmonic and interharmonic components below 1920 Hz in the signal.
(b) When SNR is about 70 dB, S-LMS using a data window length of 1/60 seconds still produces accurate measurement of all harmonic and interharmonic components.
(c) However, if SNR is lower than 60 dB, S-LMS using a data window length of 1/60 seconds may not generate reasonably accurate measurements for all harmonic and interharmonic components.

For power system signals, the SNR is usually between 50 dB and 70 dB. Therefore, a data window length of 1/30 seconds is recommended.

### EXPERIMENTAL DATA

The experiments below were performed to validate the effectiveness of the S-LMS method of the present disclosure, and to demonstrate its ultra-high frequency resolution, enhanced noise immunity, and capability of handling fundamental frequency deviations. For all test cases below, the sampling frequency is set at 3840 Hz. The data window length is 1/30 seconds, meaning 128 sample points under the 3840 Hz sampling rate.

### Frequency Resolution Test

Two cases were investigated to show the high frequency resolution of the S-LMS method of the present disclosure.

Case 1:

$$x ( n ) = {\sum }_{i}^{ } {A}_{i} cos ( n 2 π {f}_{i} Δ t + {φ}_{i} ) ,$$

where values of Aᵢ, fᵢ, and φᵢ are given in Table I below. The test signal is composed of five tones: fundamental frequency component at 60 Hz, 9^{th} harmonic at 540 Hz, and three interharmonic components at 98 Hz, 252 Hz and 312 Hz.

TABLE I
Table I: Signal Parameters and Measurement Results Using S-LMS
SIGNAL PARAMETERS AND MEASUREMENT RESULTS
USING S-LMS

| | | | | | | |
|---|---|---|---|---|---|---|
| Aᵢ | Actual values | 1.00 | 0.20 | 0.10 | 0.10 | 0.02 |
| (pu) | Measured values | 1.00 | 0.20 | 0.10 | 0.10 | 0.02 |
| fᵢ | Actual values | 60.0 | 98.0 | 252.0 | 312.0 | 540.0 |
| (Hz) | Measured values | 60.0 | 98.0 | 252.0 | 312.0 | 540.0 |
| φᵢ | Actual values | 0.00 | 60.00 | 30.00 | 0.00 | 90.00 |
| (°) | Measured values | 0.00 | 60.00 | 30.00 | 0.00 | 90.00 |

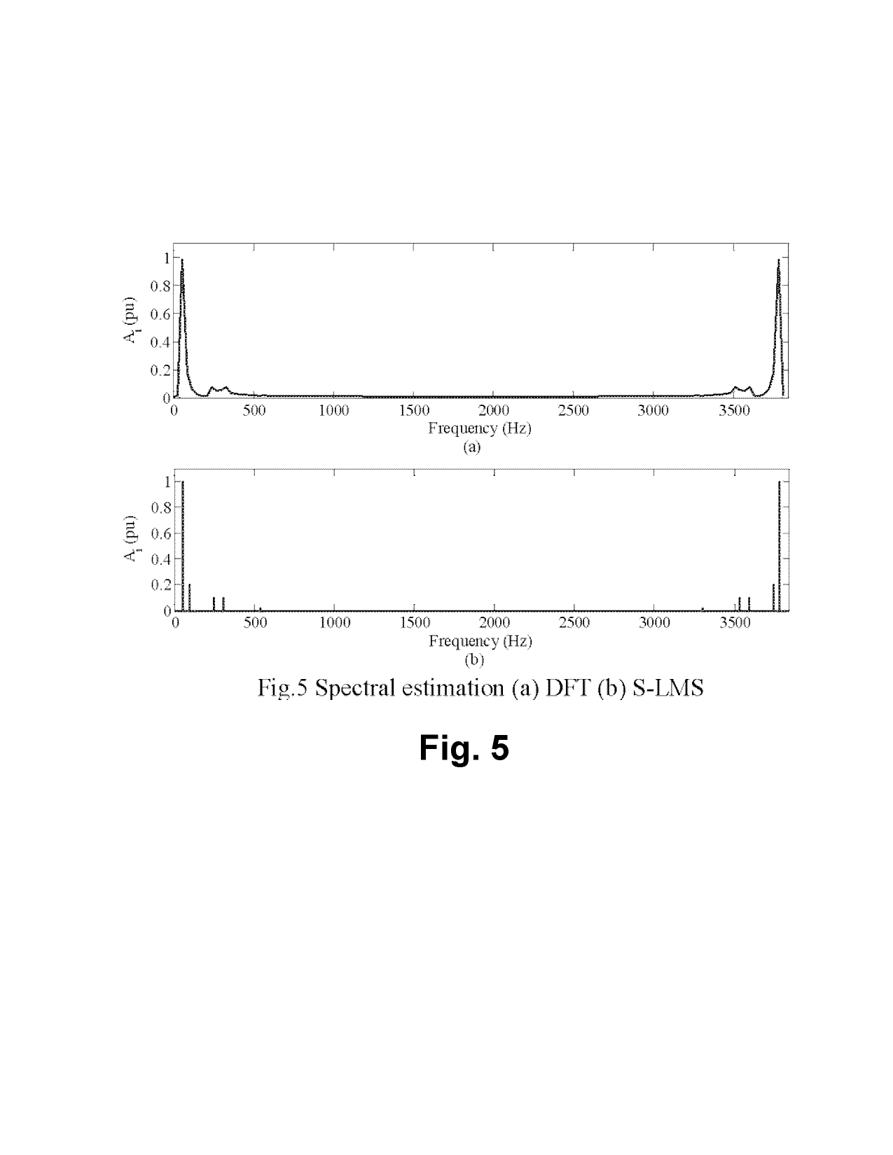

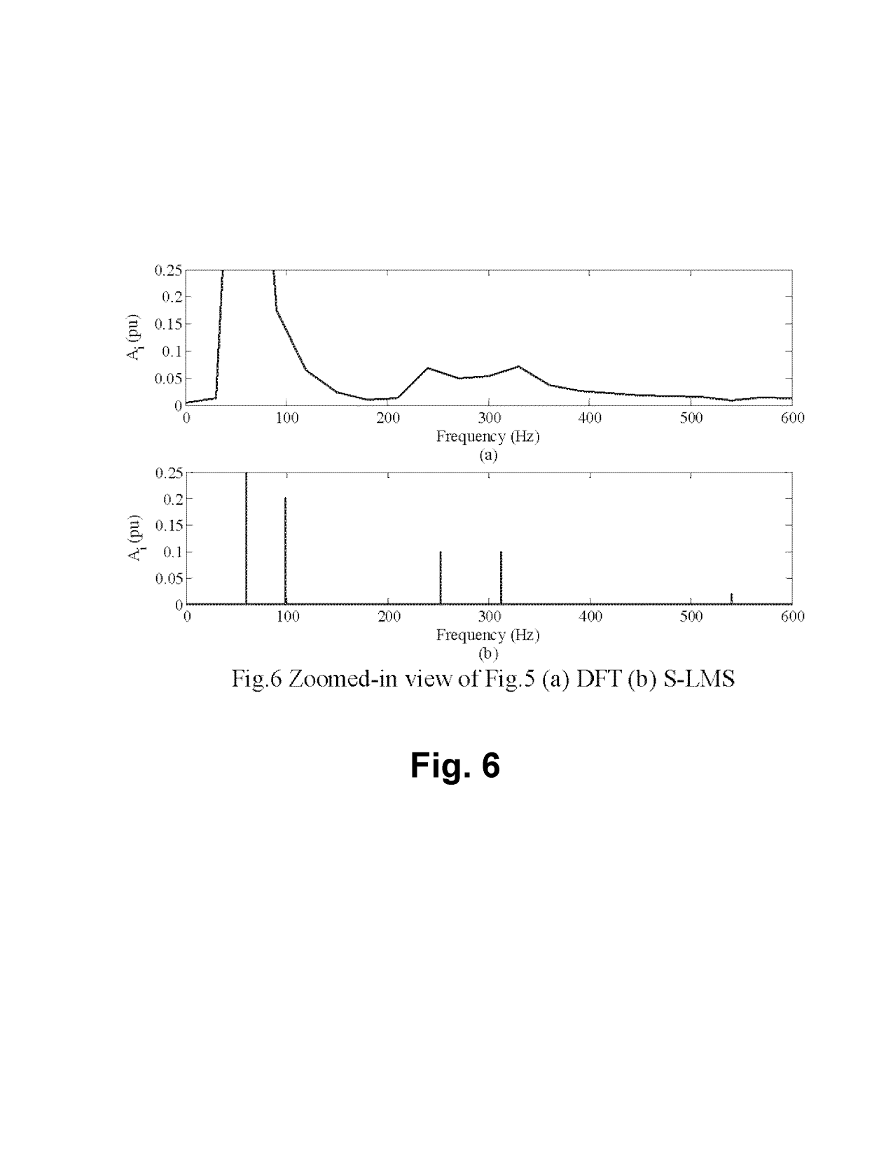

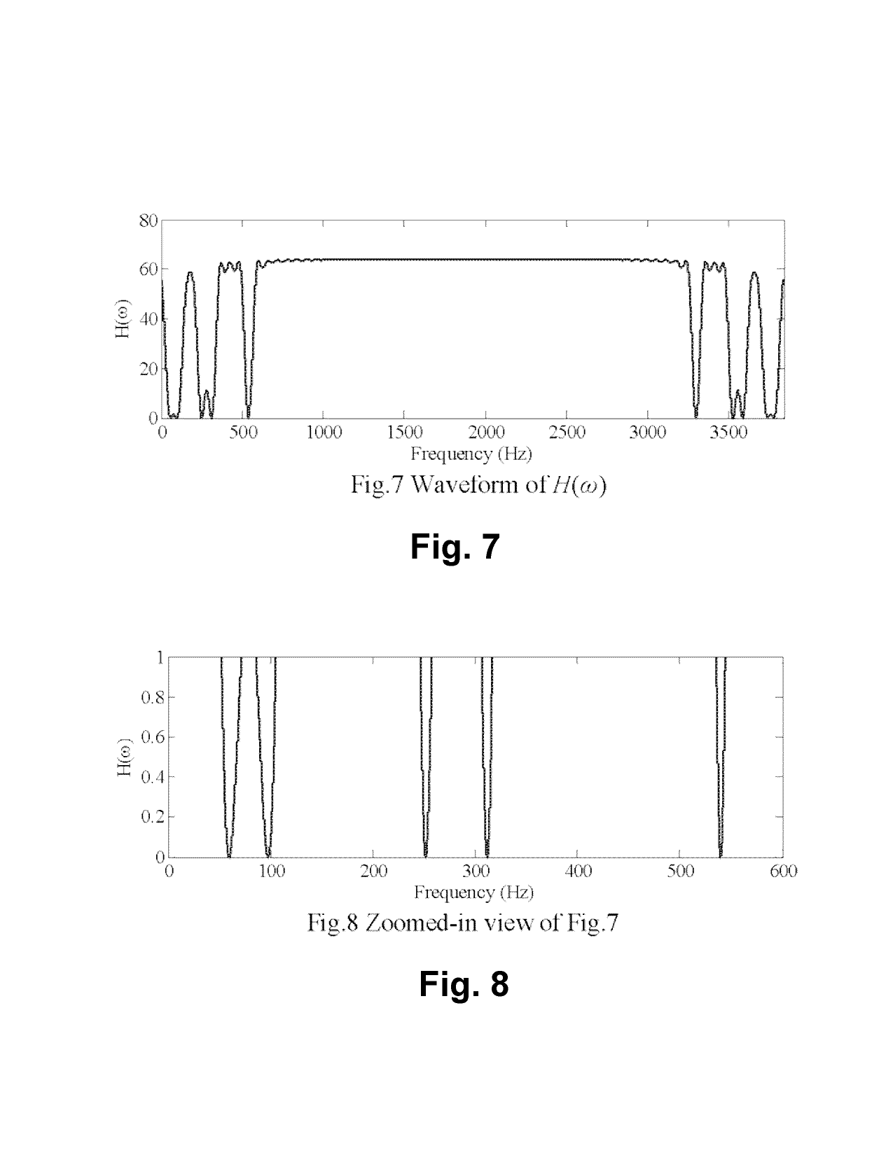

The spectra obtained by Discrete Fourier transform (DFT) and by S-LMS are illustrated in FIGS. 5(a) and 5(b), respectively. FIG. 6(a) is a magnified view of a portion of FIG. 5(a), and FIG. 6(b) is a magnified view of a portion of FIG. 5(b) in the area where the x-axis is from 0 to 600 Hz and the y-axis is from 0 to 0.25. As can be seen most clearly in FIG. 6(a), the DFT failed to provide accurate measurement of the harmonic and interharmonic components. For example, the components at 60 Hz and 98 Hz cannot be separated from each other, and the 9^{th} harmonic at 540 Hz cannot be separated from the leakage components of DFT. On the other hand, S-LMS gives an exact spectrum and hence highly accurate measurement. FIG. 6(b) shows that all components are clearly separated and amplitudes are correctly computed. In fact, the measurement results by S-LMS are identical to actual parameters of the test signal, as summarized in Table I above. Therefore, S-LMS shows superior performance in terms of resolution than DFT. The waveform of H(ω) is shown in FIG. 7, with a magnified view in FIG. 8.

Case 2: x(t)=cos(2πf₁t+φ₁)+0.2 cos(2πf₂t+φ₂), where f₁=60 Hz, f₂=60.2 Hz, φ₁=0, and φ₂=π/6.

Case 2 was a study to verify the ultra-high resolution of S-LMS. The test signal carries two components with a frequency difference of Δf=0.2 Hz. To separate these two components in Case 2, the DFT method needs a data window length longer than 1/Δf, that is, at least 5 seconds. In contrast, S-LMS does not have such stringent limitations, and can separate the two components accurately with a data window of 1/30 seconds.

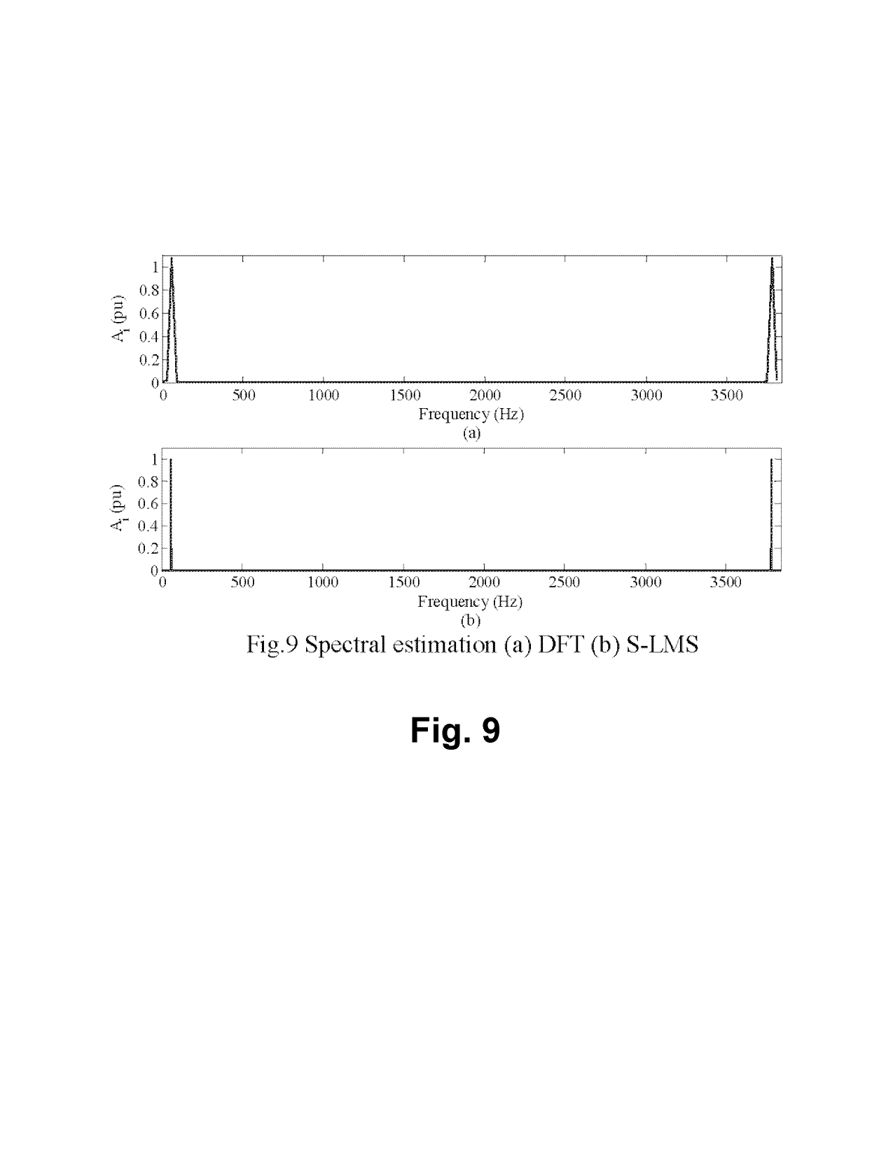

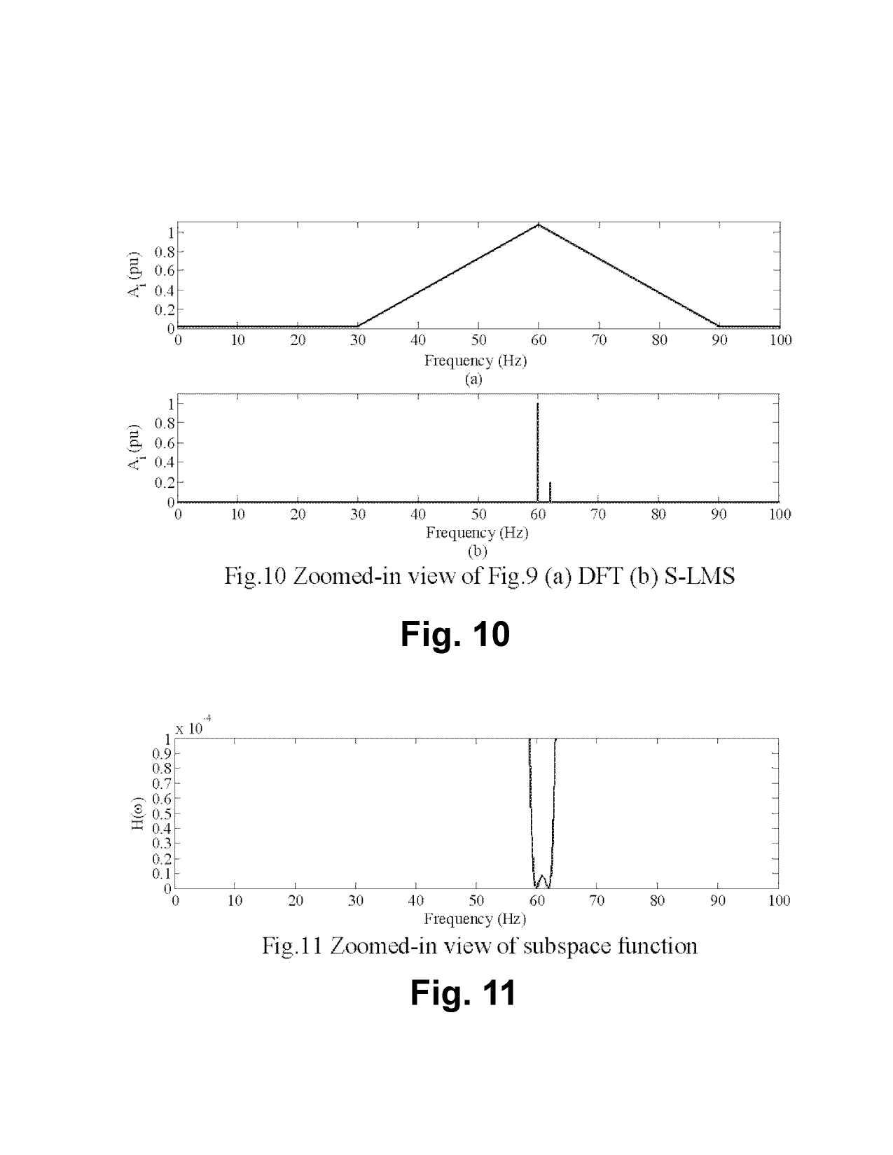

FIG. 9(a) and FIG. 9(b) show the spectra obtained by DFT and S-LMS, respectively, with a data window length of 1/30 seconds. FIG. 10(a) is a magnified view of a portion of FIG. 9(a), and FIG. 10(b) is a magnified view of a portion of FIG. 9(b) in the area where the x-axis is from 59.9 to 60.3 Hz and the y-axis is from 0 to 1e-5. From FIGS. 9 and 10, it can be seen that DFT was unable to distinguish the two components. Instead, they are merged together in the DFT spectrum. However, the spectra show that S-LMS is able to clearly separate the two components and to provide correct amplitudes as well. As summarized in Table II below, the parameters obtained using S-LMS are identical to the actual values. FIG. 11 shows a portion of the H(ω) waveform.

TABLE II
Signal Parameters and Measurement Results Using S-LMS
TABLE II
SIGNAL PARAMETERS AND MEASUREMENT
RESULTS USING S-LMS

| | | | |
|---|---|---|---|
| Aᵢ | Actual value | 1.00 | 0.20 |
| (pu) | Measured value | 1.00 | 0.20 |
| fᵢ | Actual value | 60.0 | 60.2 |
| (Hz) | Measured value | 60.0 | 60.2 |
| φ | Actual value | 0.00 | 30.00 |
| (°) | Measured value | 0.00 | 30.00 |

### Noise Effect Test

In Case 3, S-LMS was also studied under various noise levels.

Case 3:

$$x ( n ) = {\sum }_{i}^{ } {A}_{i} cos ( n 2 π {f}_{i} Δ t + {φ}_{i} ) + w ( n )$$

where w(n) is a white noise such that SNR is 50 dB, and values of Aᵢ, fᵢ, and φᵢ are given in Table III below.

TABLE III
Table III; Signal Parameters and Measurement Results Using
S-LMS (SNR = 50 dB)
SIGNAL PARAMETERS AND MEASUREMENT RESULTS
USING S-LMS (SNR = 50 DB)

| | | | | | | |
|---|---|---|---|---|---|---|
| Aᵢ | Actual value | 1.00 | 0.20 | 0.10 | 0.10 | 0.02 |
| (pu) | Measured value | 1.00 | 0.20 | 0.10 | 0.10 | 0.02 |
| fᵢ | Actual value | 60.0 | 98.0 | 252.0 | 312.0 | 540.0 |
| (Hz) | Measured value | 60.0 | 98.0 | 252.0 | 312.0 | 539.6 |
| φᵢ | Actual value | 0.00 | 60.00 | 30.00 | 0.00 | 90.00 |
| (°) | Measured value | 0.00 | 59.89 | 29.96 | 0.00 | 89.50 |

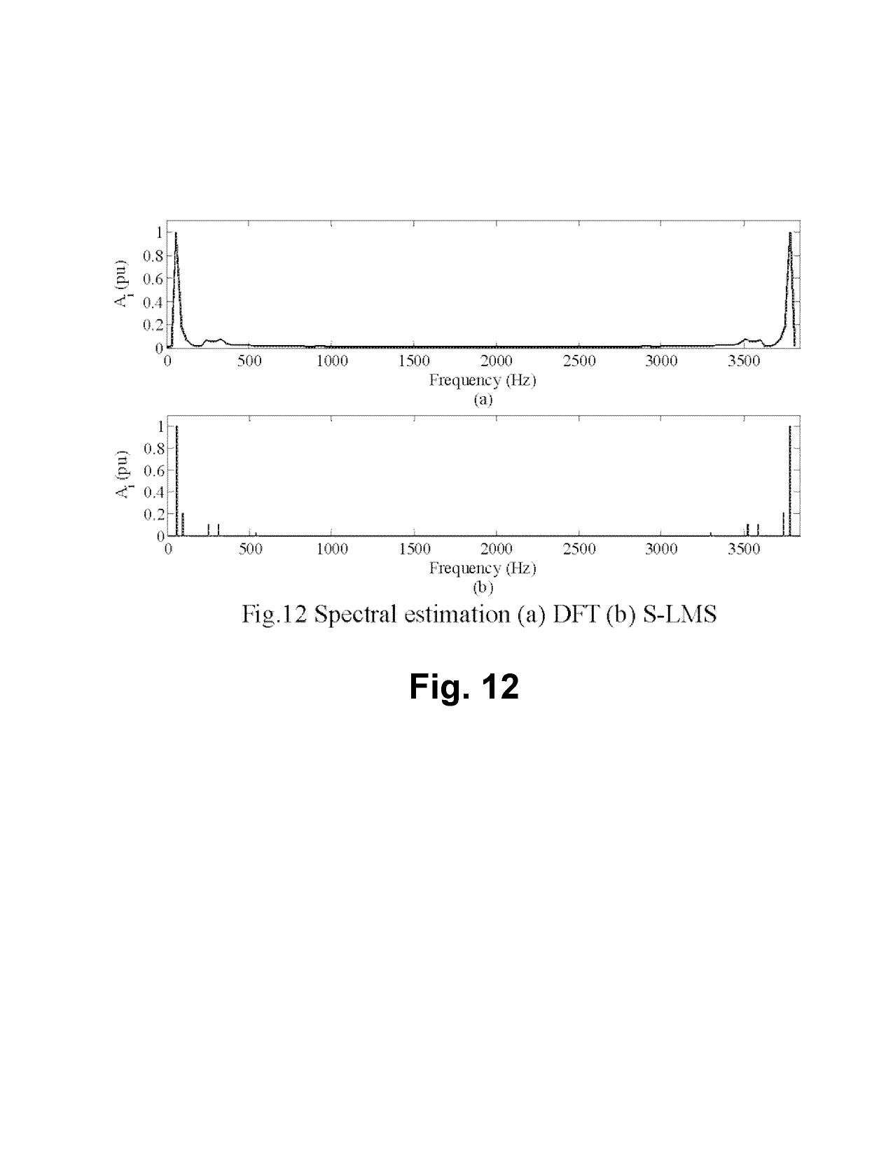

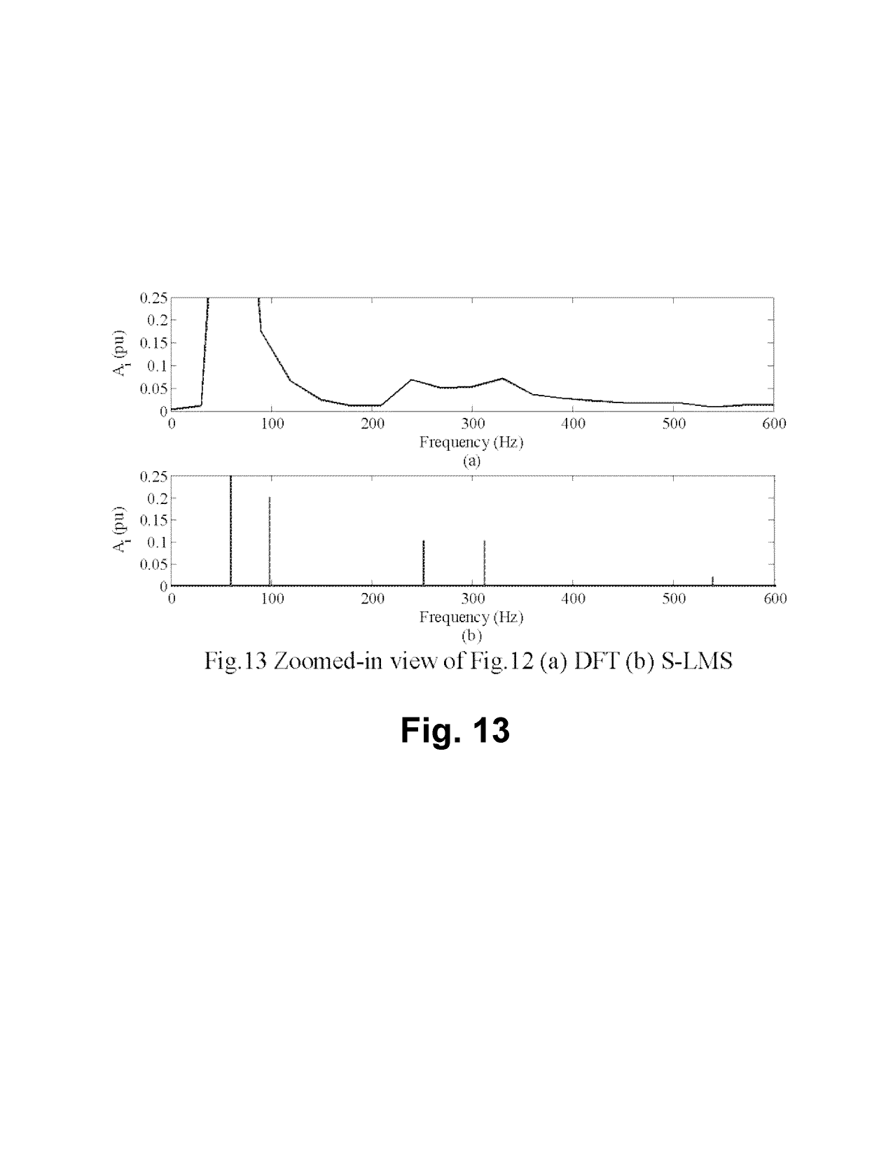

The signal in Case 3 is similar to that in Case 1, with the only exception of the 50 dB white noise. FIGS. 12(a) and 12(b) are the spectra obtained using DFT and S-LMS methods, respectively. FIG. 13(a) is a magnified view of a portion of FIG. 12(a), and FIG. 13(b) is a magnified view of a portion of FIG. 12(b) in the area where the x-axis is from 0 to 100 Hz and the y-axis is from 0 to 0.25.

From these results, it can be seen that S-LMS provided high levels of precision even in a noisy environment, while DFT failed to give accurate measurements with the 50 dB noise.

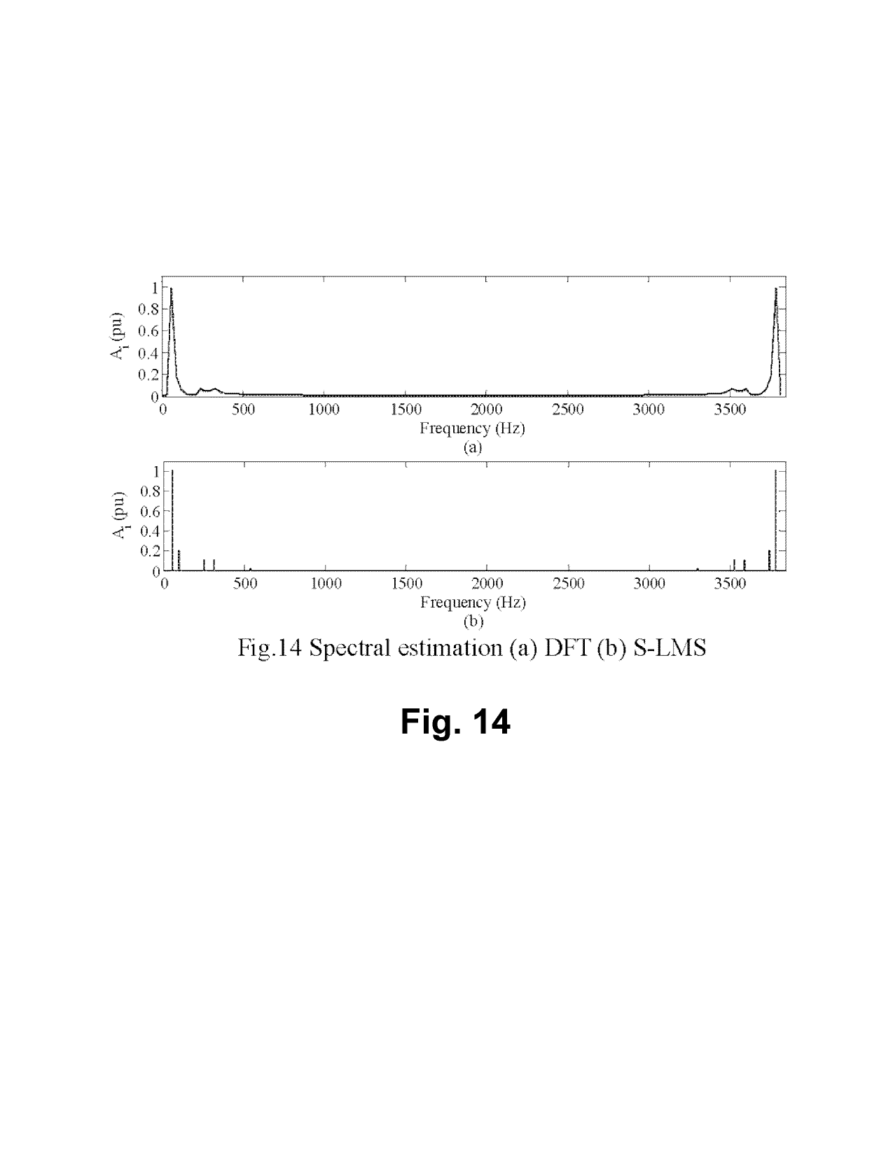

As shown in FIGS. 14(a) and 14(b), and in Table IV below, when SNR was decreased to 40 dB, S-LMS was still able to achieve accurate results on all harmonics and interharmonics of interest, with a data window length of 1/30 seconds. On the other hand, DFT failed to provide satisfactory results under this scenario. These experiments show when the SNR decreases to 20 dB that the performance of S-LMS degrades without being able to provide accurate measurement. Power systems have SNR that are usually within a range from 50 dB to 70 dB. Therefore, S-LMS is able to provide accurate measurements for power systems having the typical noise ranges.

TABLE IV
Table IV: Signal Parameters and Measurement Results Using
S-LMS (SNR = 40 dB)
SIGNAL PARAMETERS AND MEASUREMENT RESULTS
USING S-LMS (SNR = 40 DB)

| | | | | | | |
|---|---|---|---|---|---|---|
| Aᵢ | Actual value | 1.00 | 0.20 | 0.10 | 0.10 | 0.02 |
| (pu) | Measured value | 0.99 | 0.20 | 0.10 | 0.10 | 0.02 |
| fᵢ | Actual value | 60.00 | 98.00 | 252.00 | 312.00 | 540.00 |
| (Hz) | Measured value | 60.01 | 98.12 | 252.24 | 312.12 | 538.62 |
| φᵢ | Actual value | 0.00 | 60.00 | 30.00 | 0.00 | 90.00 |
| (°) | Measured value | 0.00 | 58.89 | 29.37 | 0.03 | 85.65 |

### Fundamental Frequency Deviation

Large frequency excursion will occur under dynamic or stressed conditions. Even under normal conditions, fundamental frequency deviations up to ±2 Hz may still be allowed. Case 4 was a performance test under fundamental frequency variations for S-LMS implementation.

$$Case 4 \text{:} x ( n ) = {\sum }_{i}^{ } {A}_{i} cos ( n 2 π {f}_{i} Δ t + {φ}_{i} ) + w ( n ) ,$$

where w(n) is a white noise at a SNR of 50 dB, and values of Aᵢ, fᵢ, and φᵢ are given in Table V below.

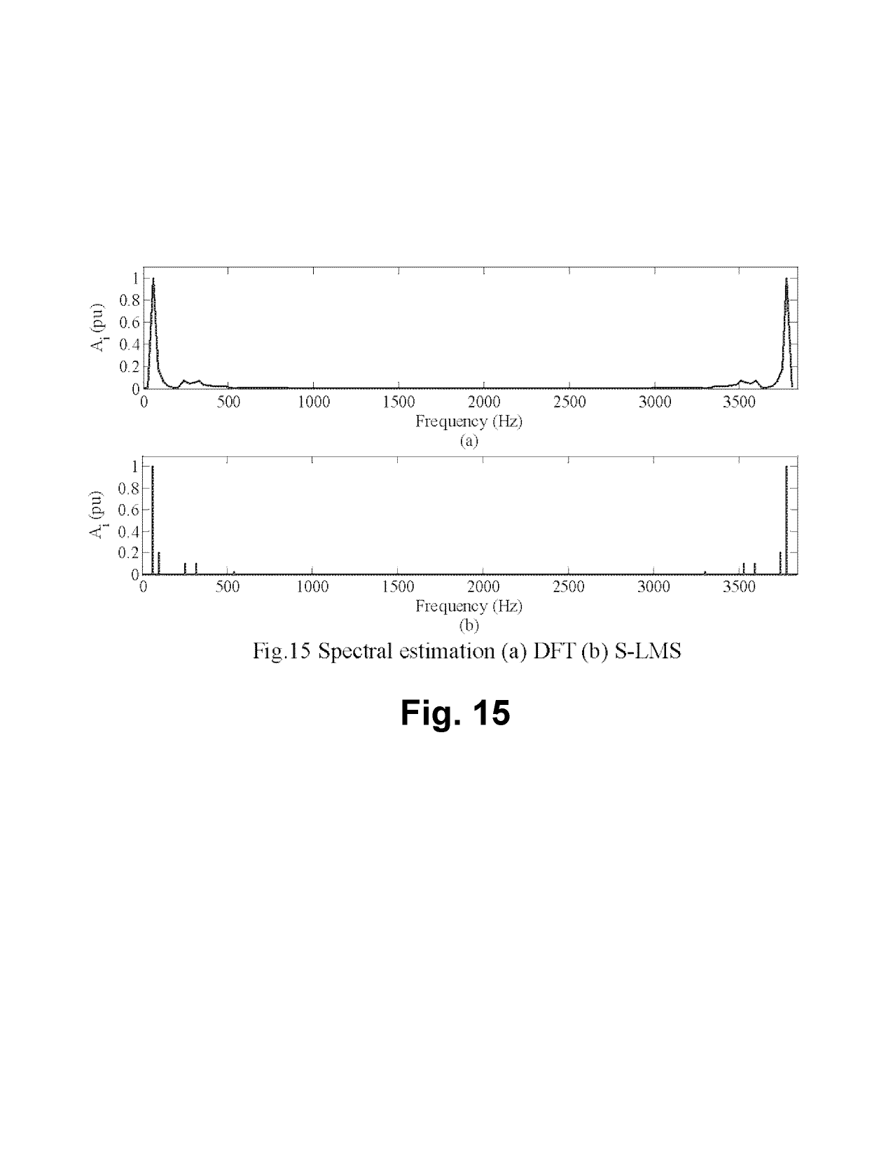

The test signal in Case 4 is a variation of the signal in Case 1, with 0.1 Hz deviation in fundamental frequency and 0.9 Hz deviation in the 9^{th} harmonic. FIGS. 15(a) and 15(b) are the spectra obtained using DFT and S-LMS methods, respectively. FIG. 15(b) and Table V show that S-LMS achieved high levels of precision, whereas FIG. 15(a) shows that DFT was unable to provide an accurate spectral estimation.

TABLE V
Table V: Signal Parameters and Measurement Results Using S-LMS
SIGNAL PARAMETERS AND MEASUREMENT RESULTS
USING S-LMS

| | | | | | | |
|---|---|---|---|---|---|---|
| Aᵢ | Actual value | 1.00 | 0.20 | 0.10 | 0.10 | 0.02 |
| (pu) | Measured value | 1.00 | 0.20 | 0.10 | 0.10 | 0.02 |
| fᵢ | Actual value | 60.1 | 98.0 | 252.0 | 312.0 | 540.9 |
| (Hz) | Measured value | 60.1 | 98.1 | 251.9 | 312.0 | 540.8 |
| φᵢ | Actual value | 0.00 | 60.00 | 30.00 | 0.00 | 90.00 |
| (°) | Measured value | 0.00 | 59.89 | 30.01 | 0.00 | 89.01 |

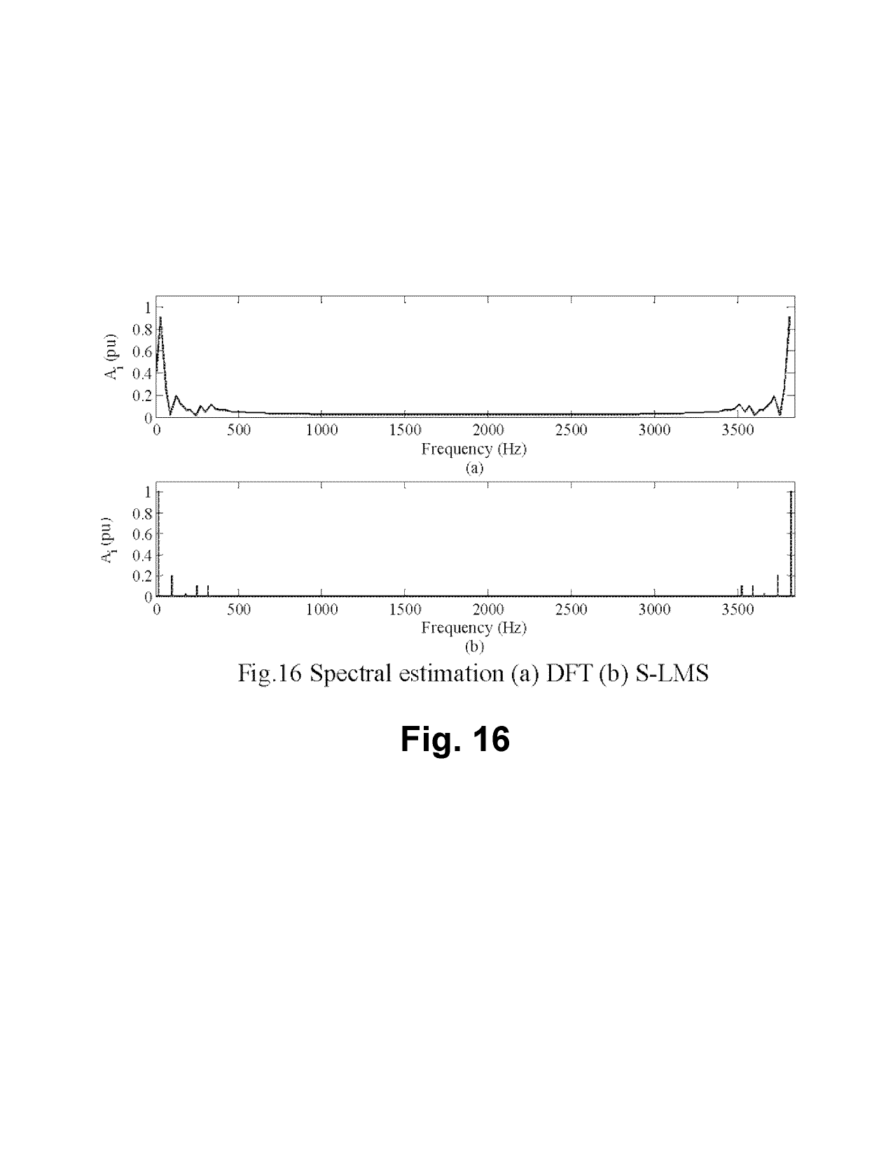

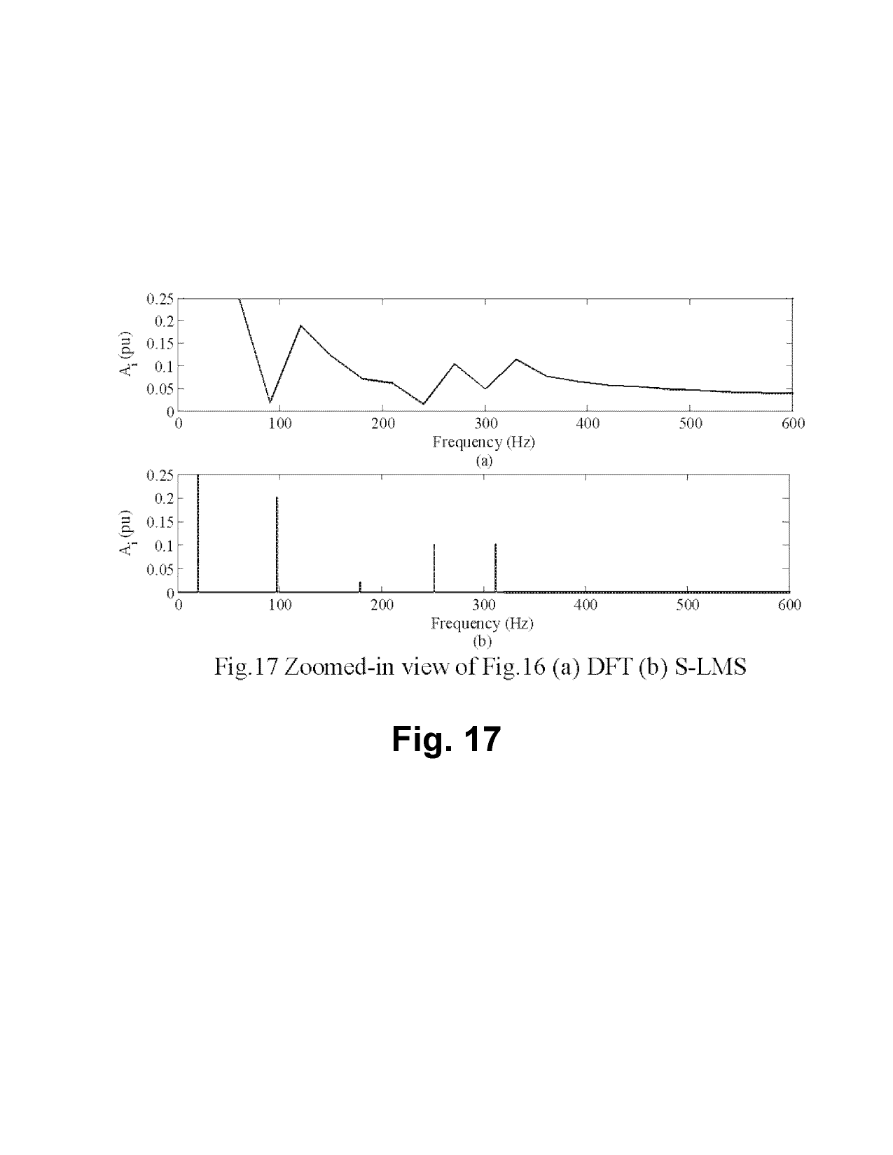

Under extreme situations such as voltage collapses or transient instabilities, frequency deviations could be large. To study the performance of S-LMS in these situations, a fundamental frequency deviation up to 20 Hz and the 9^{th} harmonic frequency deviation up to 180 Hz were studied using the model of Case 4. The results are summarized in Table VI and in FIGS. 16 and 17.

FIGS. 16(a) and 16(b) are the spectra obtained using DFT and S-LMS methods, respectively. FIG. 17(a) is a magnified view of a portion of FIG. 16(a), and FIG. 17(b) is a magnified view of a portion of FIG. 16(b) in the area where the x-axis is from 0 to 600 Hz and the y-axis is from 0 to 0.25. Surprisingly, S-LMS still produces accurate measurements of all components in the signal, which is in sharp contrast to DFT, which is not longer able to work properly under this situation. Frequency deviation, therefore, appears to have almost no effect on S-LMS performance.

TABLE VI
Table VI: Signal Parameters and Measurement Results Using S-LMS
SIGNAL PARAMETERS AND MEASUREMENT RESULTS
USING S-LMS

| | | | | | | |
|---|---|---|---|---|---|---|
| Aᵢ | Actual value | 1.00 | 0.20 | 0.10 | 0.10 | 0.02 |
| (pu) | Measured value | 1.00 | 0.20 | 0.10 | 0.10 | 0.02 |
| fᵢ | Actual value | 20.0 | 98.0 | 252.0 | 312.0 | 180.0 |
| (Hz) | Measured value | 20.0 | 97.9 | 251.9 | 312.1 | 179.7 |
| φᵢ | Actual value | 0.00 | 60.00 | 30.00 | 0.00 | 90.00 |
| (°) | Measured value | 0.00 | 59.91 | 30.44 | 0.00 | 89.22 |

Test Using Field Data from Event Recorder

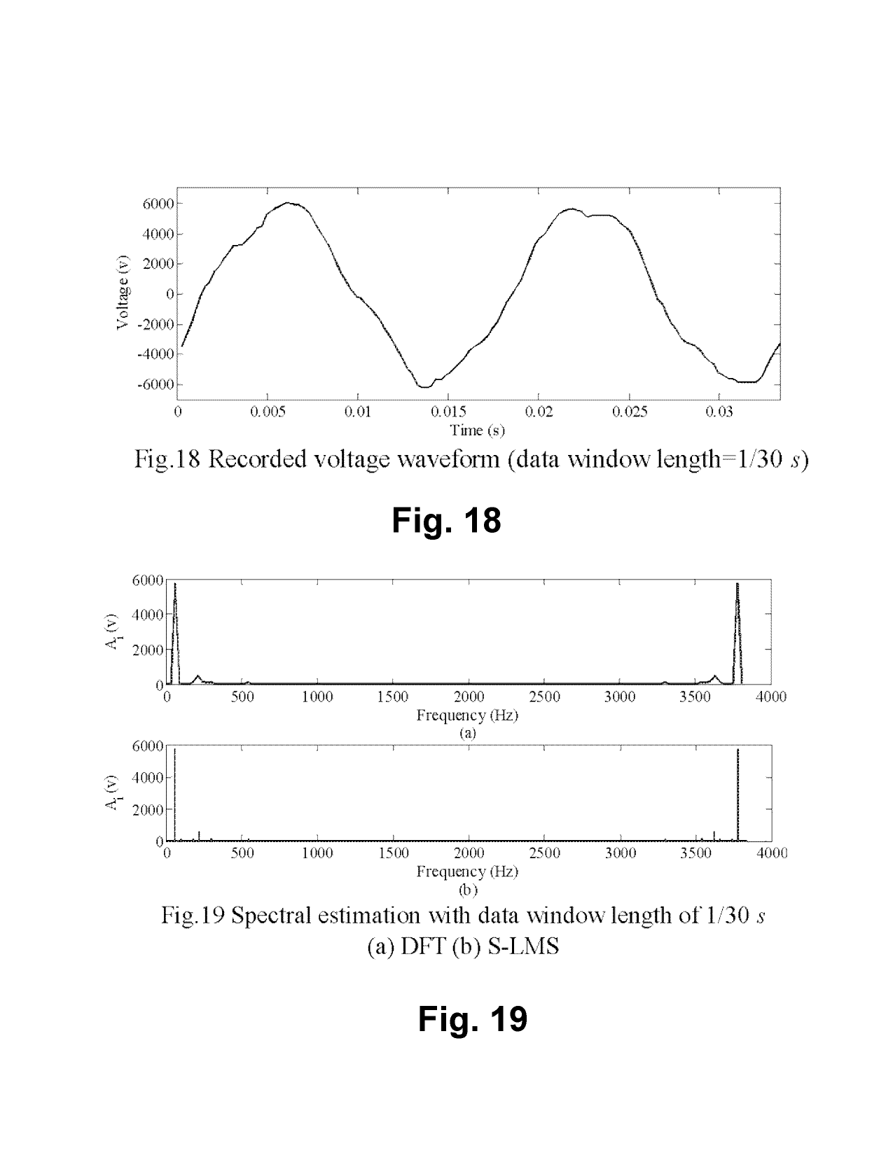

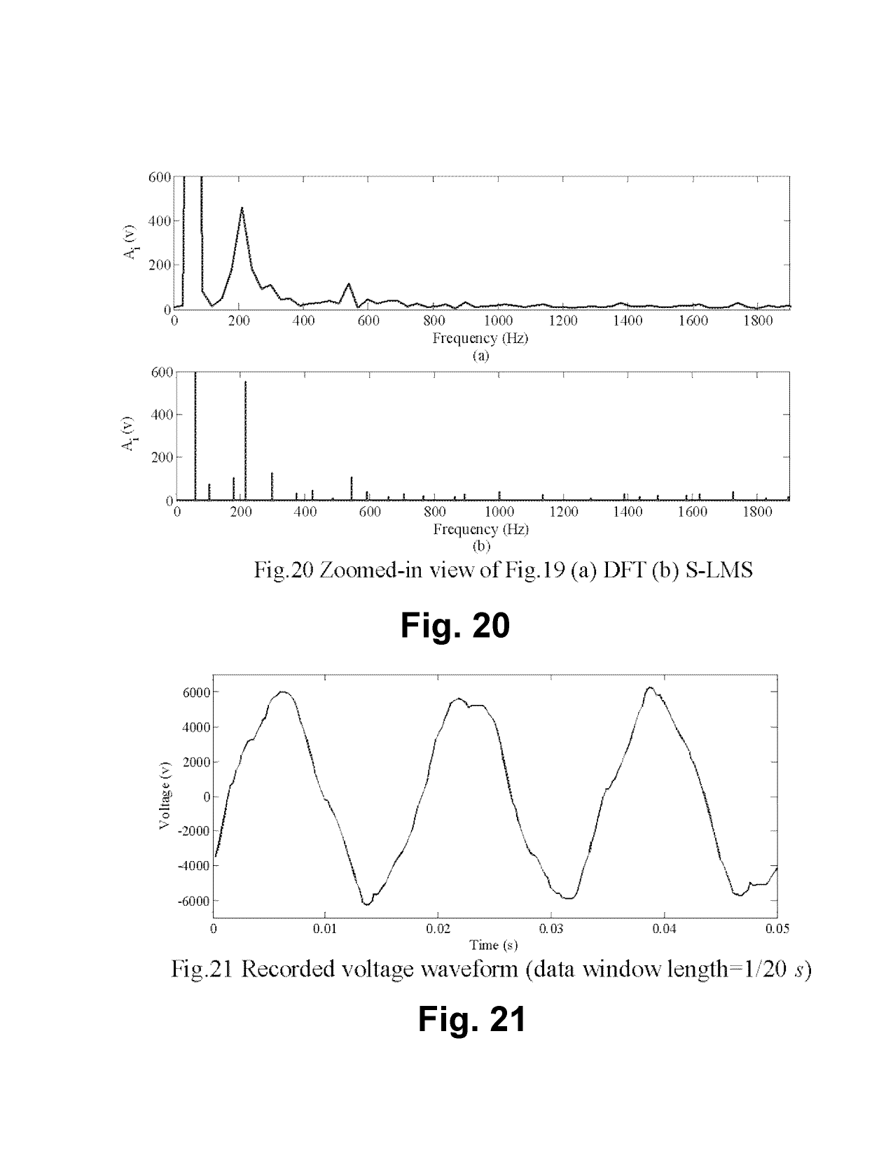

Further studies were conducted of S-LMS using a real-world power system signal recorded in the field. FIG. 18 shows the voltage signal recorded from a factory with VFD motors. The sampling rate was set to 3840 Hz and data window length at 1/30 seconds. FIGS. 19(a) and 19(b) are the spectra obtained using DFT and S-LMS methods, respectively. FIG. 20(a) is a magnified view of a portion of FIG. 19(a), and FIG. 20(b) is a magnified view of a portion of FIG. 19(b) in the area where the x-axis is from 0 to about 1900 Hz and the y-axis is from 0 to 600. As can be seen in FIGS. 19 and 20, the spectra obtained using DFT and S-LMS are different: the spectrum using S-LMS shows some harmonic/interharmonic components that exist which are not apparent in the spectrum using DFT.

To test whether these harmonic/interharmonic components actually exist, or are just some spurious numerical results introduced by the S-LMS method itself, the data window of the test signal was extended to 1/20 seconds, based on the reasonable assumption that harmonic/interharmonic components do not change during such a short time span.

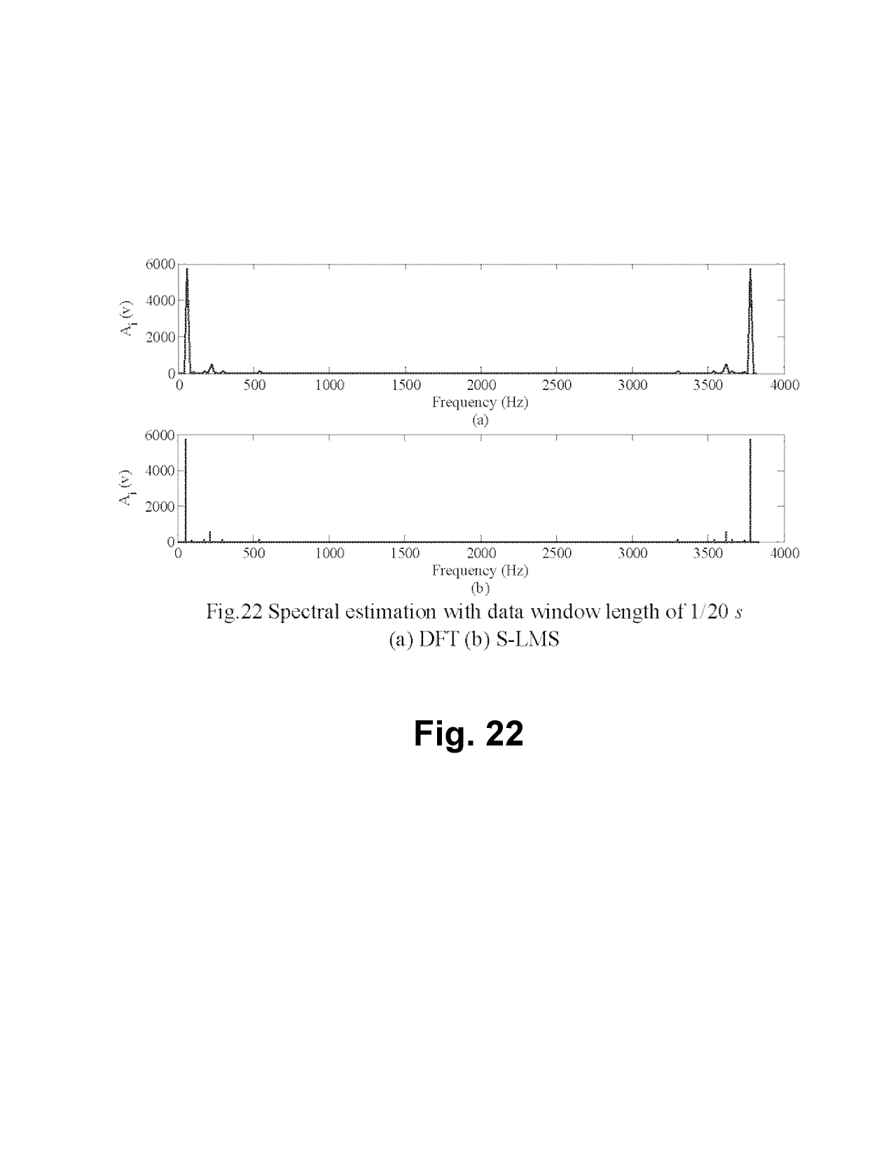

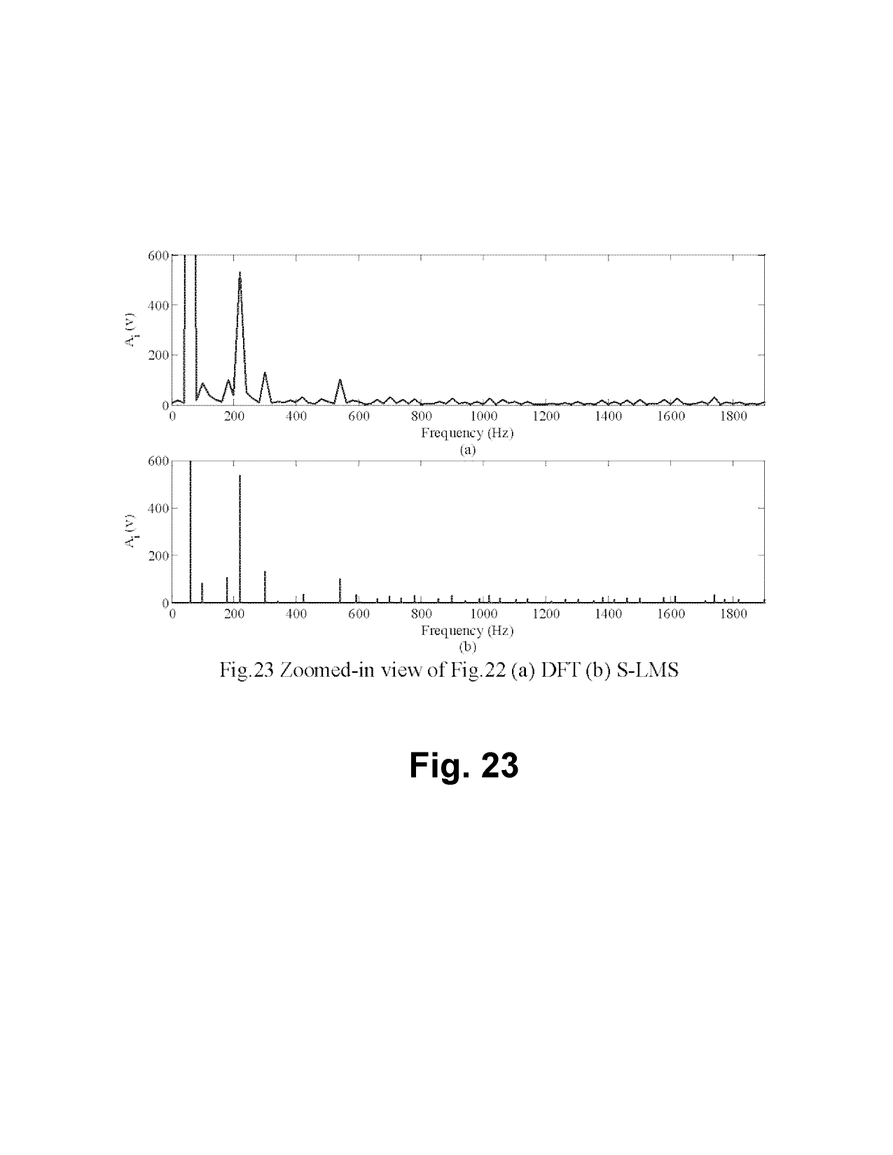

FIG. 21 shows the 1/20 second waveform of the test signal. Note that with the increase of data window length, the precision of DFT will increase due to enhanced frequency resolution capability. FIGS. 22(a) and 22(b) are the spectra obtained using the DFT and S-LMS methods, respectively. FIG. 23(a) is a magnified view of a portion of FIG. 22(a), and FIG. 23(b) is a magnified view of a portion of FIG. 22(b) in the area where the x-axis is from 0 to about 1900 Hz and the y-axis is from 0 to 600.

By comparing the results from the two different data window lengths, it was found that:
(a) Some peaks previously not apparent in the DFT spectrum with the data window of 1/30 seconds become observable in DFT results with a larger data size of 1/20 seconds shown in FIG. 23(a).
(b) Spectra obtained using S-LMS stay the same regardless of changes in data window sizes, as shown in FIGS. 20(b) and 23(b).
(c) The DFT spectrum obtained with a data window of 1/20 seconds fits better to the S-LMS spectrum than the DFT spectrum with a 1/30 seconds data window length.

Therefore, this experiment answers the questions being tested, i.e., (1) S-LMS is more accurate than DFT, and (2) the harmonic/interharmonic components identified by S-LMS actually exist in the voltage signal.

With this real-world test case, the data show that that S-LMS provides more accurate estimations for phasor, harmonic and interharmonic measurements.

Despite its improved precision in FIG. 23(a) as compared with FIG. 20(a), the DFT method still has a resolution granularity of 20 Hz for the 1/20 seconds data window, meaning that it can only measure components with frequencies of integer multiples of 20 Hz, such as 20 Hz, 40 Hz, etc. In contrast, S-LMS has no such limitations, which provides ultra-high resolution capability in tracking phasors, harmonics and interharmonics within only 1/30 seconds. This makes S-LMS a powerful tool for power system monitoring and control.

The speed of the S-LMS method can be further increased by a “sparsity” scheme using the unique characteristics of power system signals. The “sparsity” scheme is also called the “heuristic” scheme herein without a change in meaning.

Searching for the entire frequencies from dc to Nyquist frequency is a time-consuming task, especially when a small frequency step size (high resolution) is practiced. Fortunately, when dealing with power system signals (current or voltage signals), prior knowledge about the characteristics of the signal can be applied.

Power system signals at any condition have significant energy at the fundamental frequency which is at or around the nominal frequency; thus, the fundamental frequency could be simply found by selecting high-resolution candidate frequencies around the nominal frequency.

Another unique feature of power system signals is that the signals may contain some harmonics which are integer multiples of the fundamental frequency (either the fundamental frequency is nominal or off-nominal). Once the fundamental frequency is estimated, the only potential candidates for the harmonics are the integer multiples of that fundamental frequency. Therefore, instead of using a series of candidate frequencies around each possible harmonic, only one candidate frequency, which is an integer multiple of the fundamental frequency (already determined in the first step), has to be tested. In other words, for each harmonic, one single candidate is tested to check whether it is orthogonal to noise vectors or not. If the orthogonality condition is met, the candidate frequency is an existing harmonic in the original signal; otherwise, that harmonic does not exist in the signal. In fact, using the sparsity scheme, instead of scanning a large number of candidate frequencies, as in the original S-LMS method above, only a very sparse number of frequencies needs to be scanned. This sparsity scheme enormously eliminates the computation effort for finding harmonic components.

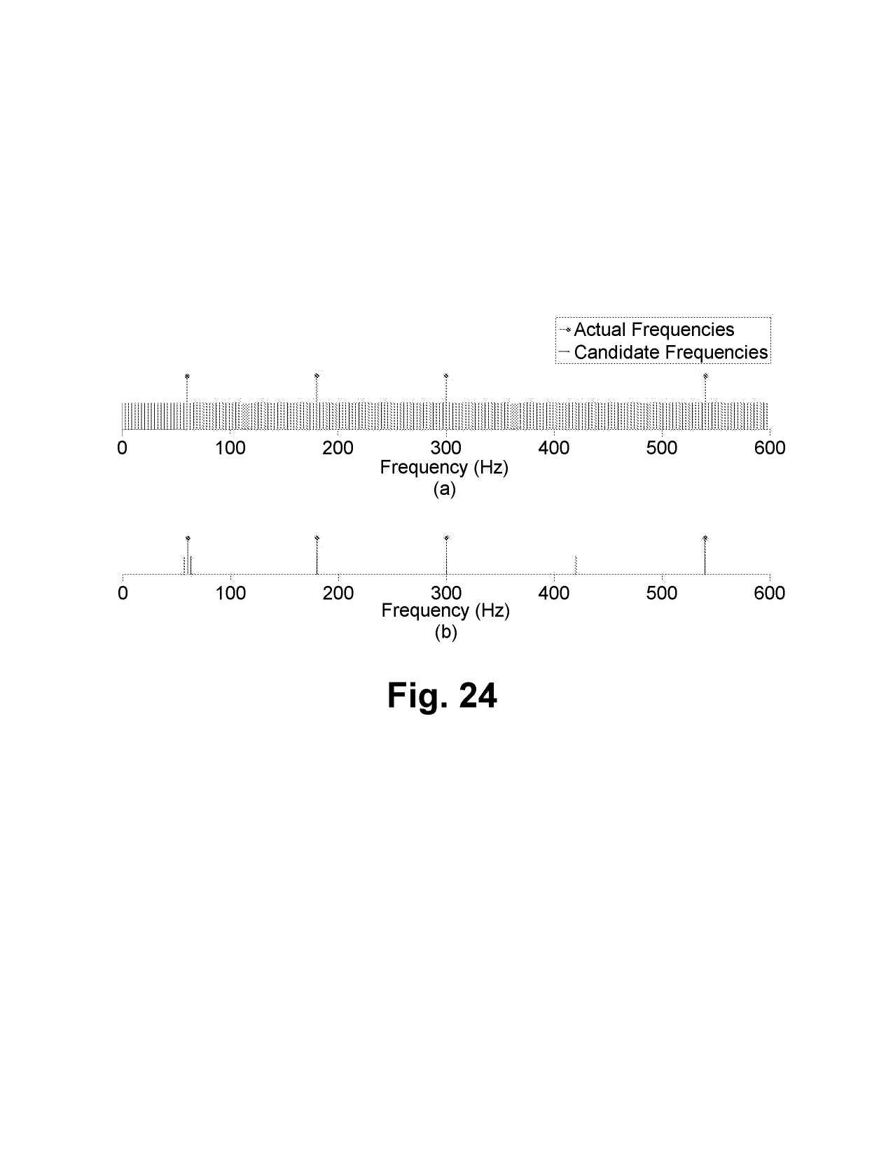

FIG. 24 shows a pictorial representation of the sparsity scheme. As FIG. 24, subpart (a) shows, in the original S-LMS method, all frequencies from dc to Nyquist frequency are among the candidate frequencies. In FIG. 24, subpart (b), however, a full scan is performed only around the nominal frequency. As can be readily perceived from the pictorial representations in FIG. 24, the computational burden of the method is significantly reduced by using this characteristic of power system signals.

The computational burden of calculating the subspace function H(ω) can be roughly (assuming that the calculations are linearly dependent on the number of candidate signals) represented as follows. Assuming the frequency resolution to be δf, the number of calculations would be, as in equation (11):

$${n}_{original} = \frac{{f}_{Nyq}}{δ f} = \frac{{f}_{s}}{2 δ f} \qquad ( 11 )$$

In the sparsity scheme, only the data around the nominal frequency of f₀ and within a limited domain of 2Δf are sought. For example, if Δf=5 Hz, the domain of search is [f₀−Δf, f₀+Δf]=[55 Hz, 65 Hz]. Therefore, the number of calculations for the sparsity scheme would be, as in equation (12):

$${n}_{sparsity} = \frac{2 Δ f}{δ f} \qquad ( 12 )$$

Hence the speed enhancement ratio r would be given by equation (13):

$$r = \frac{{n}_{original}}{{n}_{sparsity}} = \frac{{f}_{s} / 2 / δ f}{2 Δ f / δ f} = \frac{{f}_{s}}{4 Δ f} \qquad ( 13 )$$

which is, in fact, the ratio of whole possible signals (i.e., f_{Nyq}) to the region around the fundamental frequency in which the fundamental frequency is sought (i.e., 2Δf). For example, fₛ=3840 Hz and Δf=5 Hz, then r=192.

The significance of the foregoing sparsity (or heuristic) scheme or method is not restricted to cutting the computational burden, but also makes the estimation of harmonic frequencies more resilient to noise. This noise-resilient harmonic estimation stems from the fact that, in the original (i.e., unenhanced) S-LMS method, detection of the fundamental and harmonic frequencies is performed by searching the local minima of the subspace function. When the signal samples are noisy, these local minima are disturbed and deviate from their true positions. Since the fundamental frequency always has a high amplitude, its corresponding local minimum deviates insignificantly compared to the deviation of the local minima of the harmonics. Therefore, in the original S-LMS method, estimation of harmonic frequencies is not as resilient to noise as the estimation of the fundamental frequency is resilient to noise.

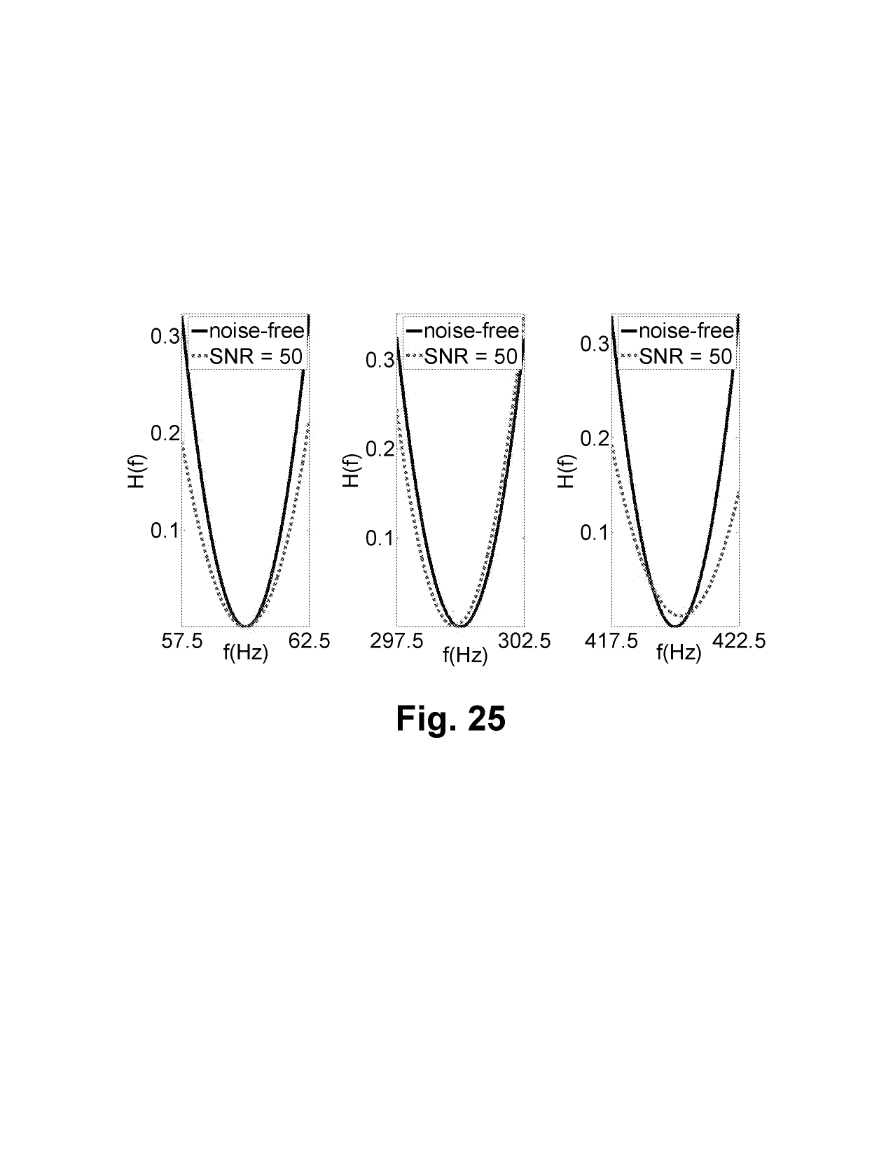

FIG. 25 illustrates what was just disclosed above by showing the subspace function around the nominal frequency and two other harmonics (5^{th} harmonic and 7^{th} harmonic) for the following signal in equation (14):

x(t)=cos(2π60t)+0.05 cos(2π300t+30°)+0.02 cos(2π420t+25°) (14)

The subspace function is plotted in two cases: (1) noise-free signal and (2) noisy signal (SNR=50 dB). As shown in FIG. 25, in the noise-free case, the local minimum of the subspace function around the nominal frequency provides an exact estimation of the fundamental frequency. In the case of the noisy signal, the subspace function around the nominal frequency is disturbed insignificantly, and more important, its pattern is preserved (i.e., the minimum of the subspace function still occurs at 60 Hz). On the other hand, the subspace function around the harmonic frequencies has been disturbed more, and more important, the local minima of the subspace function have deviated from the true frequencies of 300 Hz and 420 Hz, resulting in harmonic estimation error. Note that the minimum subspace function for the 7^{th} harmonic is affected more by noise than that of the 5^{th} harmonic. This is because the amplitude of the 5^{th} harmonic is higher than that of the 7^{th} harmonic.

Harmonic components are, by far, prone to noise compared to the fundamental. Hence, for noisy signals, proportional to the noise level, the subspace function is tilted around the harmonic components. This results in some harmonic estimation error. When the foregoing sparsity scheme is applied, however, the estimation of harmonic frequencies, instead of being based on the local minima of subspace function, is based on checking the orthogonality condition of integer multiples of the fundamental frequency (already estimated). Thus, the accuracy of detecting the harmonics becomes more resilient to noise as that of the fundamental.

As noted above, another approach to enhance the speed of the S-LMS method is the “catch-and-pinpoint” scheme. The catch-and-pinpoint scheme starts from a bird's-eye view broad scan with a rough estimate (e.g., accuracy of 5 Hz) of existing frequencies and continues with iterative fine-tuning around the suspected signals caught in the broad scan. In the first iteration (bird's-eye view step), candidate frequencies are selected over all possible spectrums (from dc to Nyquist frequency), but with very low resolution (e.g., 5 Hz), so that the computation burden becomes very low. Once very rough estimates of existing frequencies are obtained, in the next iteration, the candidate frequencies are selected with higher resolution and around the existing rough-resolution caught frequencies. This iterative method is continued until frequency components are determined with desired accuracy.

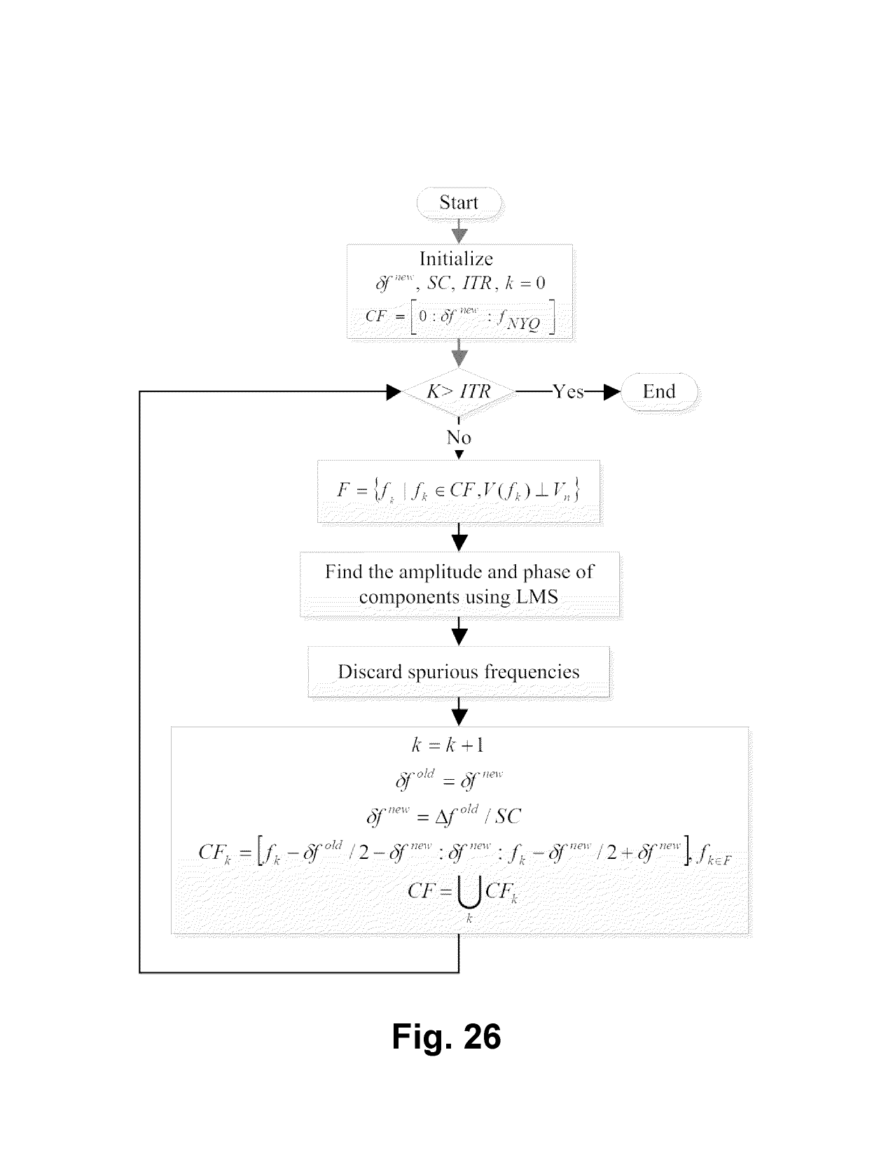

FIG. 26 is a flowchart of the catch-and-pinpoint scheme. In FIG. 26, δf is the resolution of candidate frequencies (CF). Candidate frequencies (CF) at the first iteration span the whole spectrum from dc to Nyquist frequency (f_{Nyq}) with δf being initialized with a big step size frequency (e.g., 5 Hz). In the next iteration, the step size for creating the candidate frequencies is a downscaled version of the δf^{old} (δf of the previous iteration) (i.e., δf^{new}=δf^{old}/SC), where the scaling factor SC is greater than 1 (SC>1) (in simulations, SC=10). At each iteration, the orthogonality of each candidate frequency to the noise vectors is tested (denoted by V(fₖ)⊥Vₙ in the flowchart). If the candidate signal is orthogonal to the noise vectors, it is considered as a signal frequency at that iteration. Despite the first iteration where the CF includes all frequencies from dc to Nyquist frequency, in other iterations, CF includes the union of (δf^{old}/2+δf^{new})-neighborhood around each caught frequency in the previous iteration. A δf^{new} overlap between new frequency intervals is adopted to block the possibility of missing interharmonics. Finally, it should be noted that though represented by V(fₖ)⊥Vₙ in the flowchart in FIG. 26, the orthogonality test is actually performed by finding the minima of the sum of magnitude of dot product of candidate signal frequencies by all noise vectors.

Note that different choices of parameters of the method result in different final resolutions and affect the speed of the method as well. For example, the selection of a higher value for δf in the first iteration results in faster speed; however, for interharmonics estimation or to deal with noise, lower initial δf is favorable. The choice of initial frequency resolution, therefore, is a matter of tradeoff. The simulation showed that the initial frequency resolution of δf=5 Hz is a good value for this tradeoff. The values used in simulations in this disclosure are as follows: ITR=4, SC=10, and δf in the first iteration is 5 Hz. These parameters result in the final frequency resolution of δf=0.005 Hz.

Note that in each iteration, after detection of the existing frequencies, the LMS method is applied to find the amplitude and phase of those tones. If the amplitude of an existing frequency is less than a threshold value, that tone is considered as a spurious frequency and discarded.

The following example demonstrates how the catch-and-pinpoint scheme works. The test signal is composed of the fundamental frequency and two interharmonics, as in equation (15):

x(t)=cos(2π60t)+0.05 cos(2π252t+30°)+0.003 cos(2π457.23t+25°) (15)

The catch-and-pinpoint scheme with parameters δf=5 Hz, SC=10 and ITR=4 is employed. This means that the scheme has 4 iterations. In the first iteration, the whole spectrum from dc to Nyquist frequency is scanned with a coarse frequency step size of δf=5 Hz. Since SC=10, in the second, third, and fourth iterations, the frequency step sizes are δf=0.5 Hz, δf=0.05 Hz, and δf=0.005 Hz, respectively.

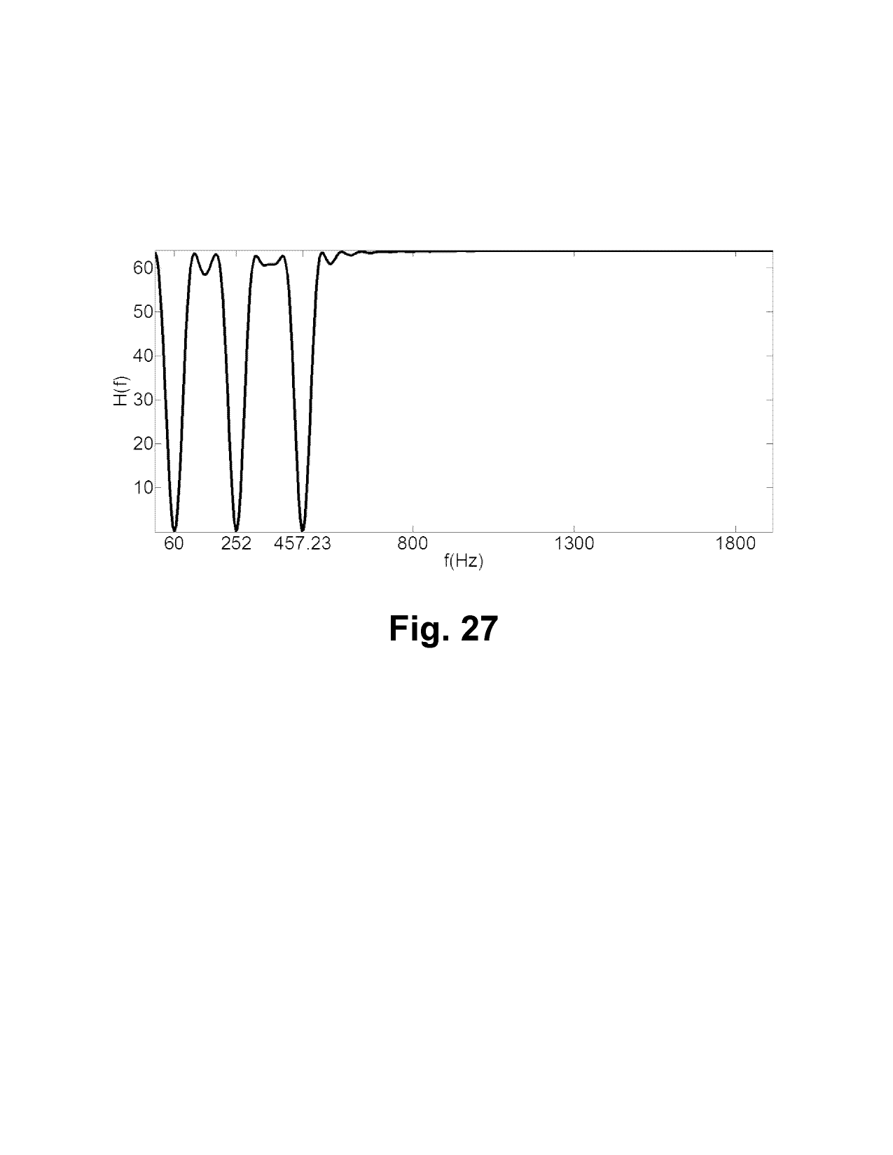

FIGS. 27 through 30 show the subspace function H(f) in the four iterations. Note that, except in the first iteration in which the candidate frequencies span the whole spectrum, in the other iterations, the candidate frequencies are a union of some separate intervals of candidate frequencies. Here, since there are three tones, the candidate signals are a union of three frequency intervals.

FIG. 27 shows the graph of subspace function H(f) computed for the whole spectrum with a coarse resolution of 5 Hz. This rough resolution is sufficient to find a rough estimate of existing frequencies. The local minima of the subspace function of H(f) in the first iteration are 60 Hz, 250 Hz, and 455 Hz.

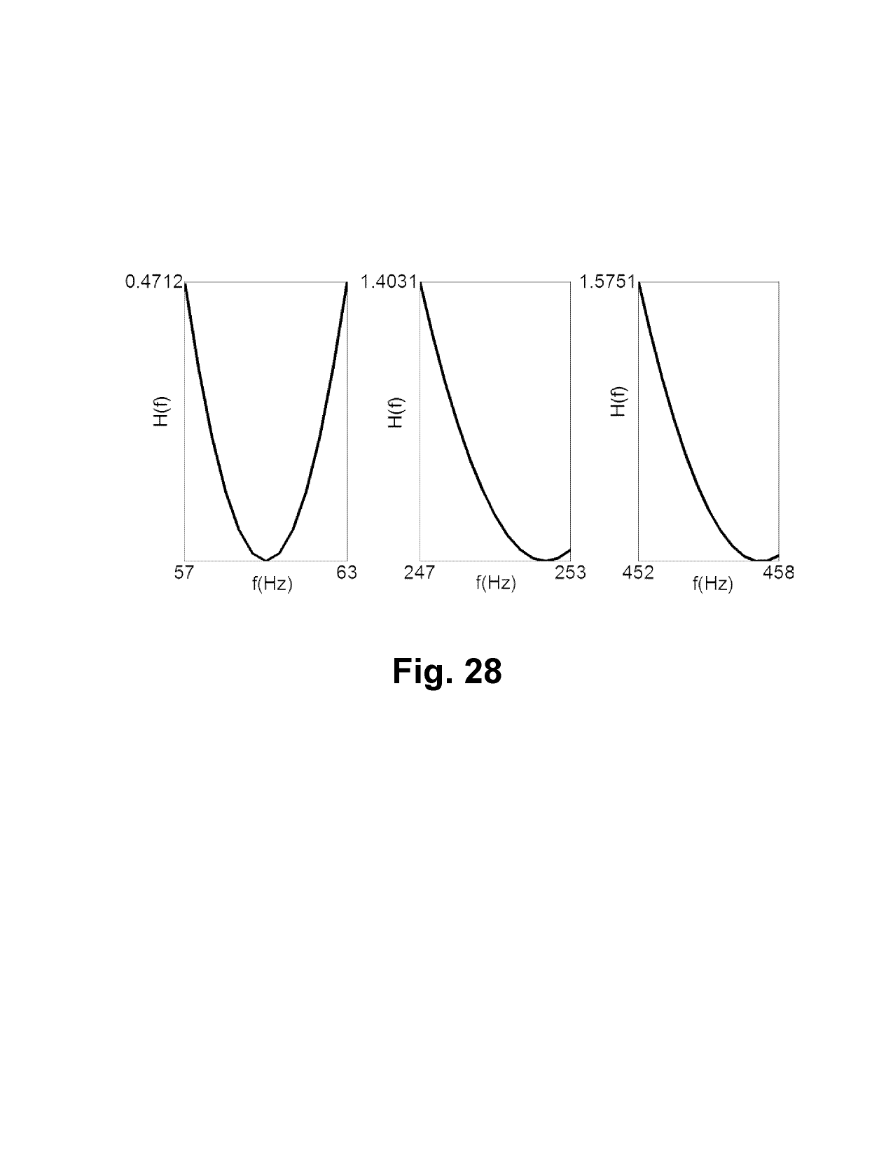

In the second iteration, δf^{new}=δf^{old}/SC=0.5 Hz and the candidate signals are selected with this resolution and in a 3-Hz neighborhood (because δf^{old}/2+δf^{new}=3 Hz) around the detected frequencies in the first iteration (i.e., around 60 Hz, 250 Hz and 455 Hz). Therefore, as illustrated in FIG. 28, the candidate frequencies are a union of three separate frequency intervals of [57, 63], [247, 253], and [452, 458]. Then, the minimum of the subspace function of H(f) with a precision of 0.5 Hz is found in each interval, which is 60.0 Hz, 252.0 Hz, and 457.0 Hz, respectively.

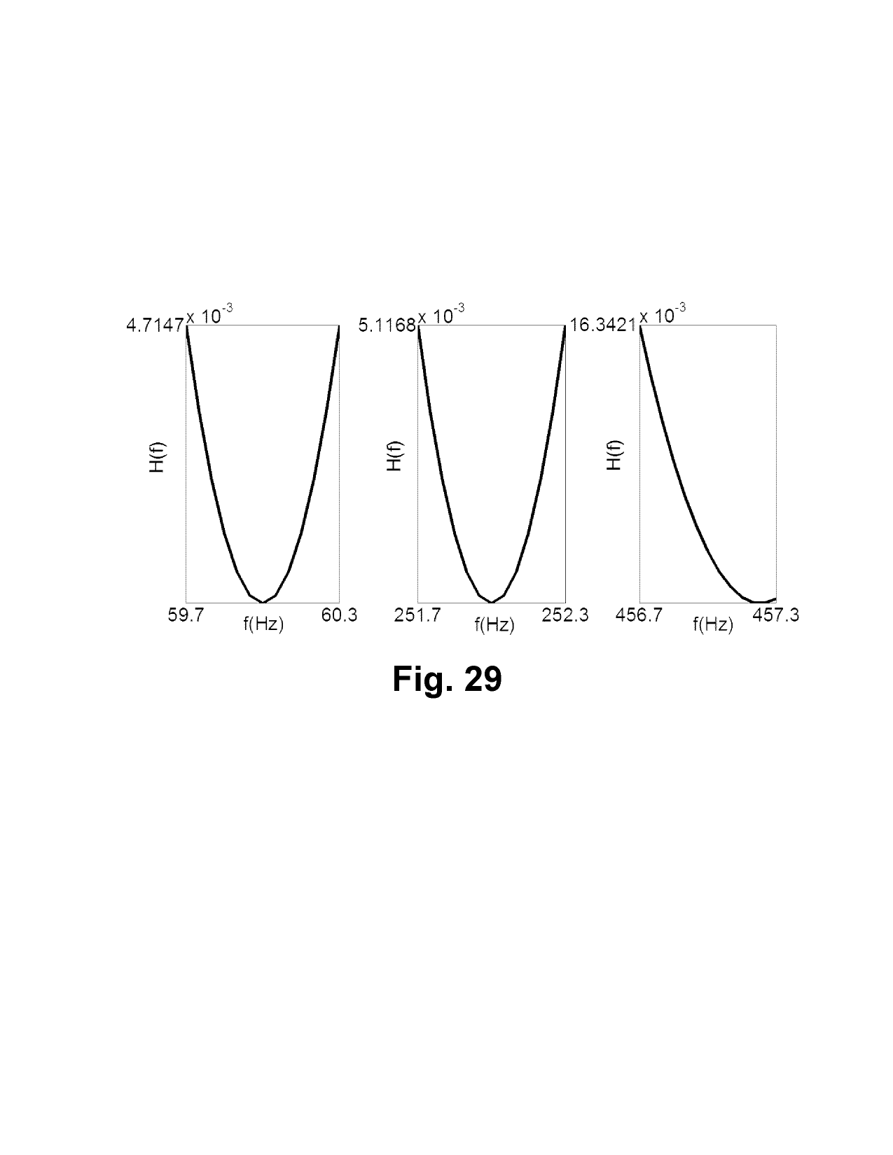

In the third iteration, δf^{new}=δf^{old}/SC=0.05 Hz and the candidate signals are selected with this resolution and in a 0.3-Hz neighborhood (because δf^{old}/2+δf^{new}=0.3 Hz) around the detected frequencies in the second iteration (i.e., around 60.0 Hz, 252.0 Hz, and 457.0 Hz). Therefore, as shown in FIG. 29, the candidate frequencies are a union of three separate frequency intervals of [59.7, 60.3], [251.7, 252.3], and [456.7, 457.3]. Then, the minimum subspace function of H(f) with a precision of 0.05 Hz is found in each interval, which is 60.00 Hz, 252.00 Hz, and 457.25 Hz, respectively.

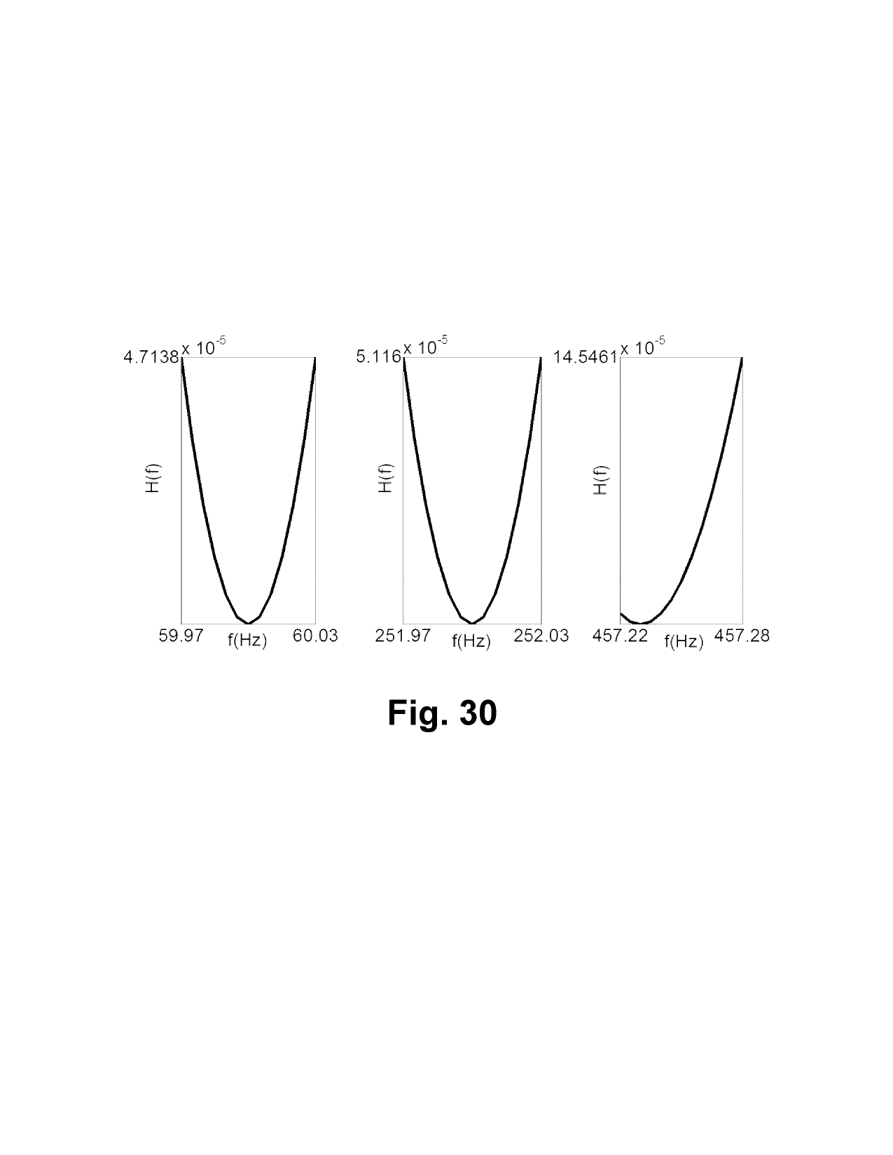

In the fourth iteration, δf^{new}=δf^{old}/SC=0.005 Hz and the candidate signals are selected with this resolution and in a 0.03-Hz neighborhood (because δf^{old}/2+δf^{new}=0.03 Hz) around the detected frequencies in the second iteration (i.e., around 60.00 Hz, 252.00 Hz, and 457.25 Hz). Therefore, as shown in FIG. 30, the candidate frequencies are a union of three separate frequency intervals of [59.97, 60.03], [251.97, 252.03], and [457.22, 457.28]. Then, the minimum subspace function of H(f) with a precision of 0.005 Hz is found in each interval, which is 60.000 Hz, 252.000 Hz, and 457.230 Hz, respectively.

Thus, the higher the amplitude of a tone, the lower the subspace function values in the neighborhood of that tone. This can be seen clearly in FIGS. 28 through 30, where the subspace function has smaller values in the neighborhood of the fundamental frequency and higher values in the neighborhood of the 252-Hz and 457.23-Hz tones.

Table VII shows the frequency, amplitude, and phase of all three tones in the four iterations above. As Table VII shows, the frequency as well as the amplitude and phase are detected roughly in the first iteration and then tuned to the true values in the next iterations. Table VII also demonstrates that, despite the frequency and phase which need several iterations to be tuned to the true values, amplitude is less sensitive to the resolution of the frequency used in the scheme, and the exact amplitude is obtained in the first iteration.

TABLE VII
Iteration Results of the Catch-and-Pinpoint Example (A) Fundamental
Frequency; (B) f = 252-Hz Tone; and (C) 457.23-Hz Tone

| | | | |
|---|---|---|---|
| Iteration | Frequency | Amplitude | Phase (degree) |

(A)

| | | | |
|---|---|---|---|
| 1 | 60 | 1.0004 | 0.0082 |
| 2 | 60.0 | 1.0000 | 0.0000 |
| 3 | 60.00 | 1.0000 | 0.0000 |
| 4 | 60.000 | 1.0000 | 0.0000 |

(B)

| | | | |
|---|---|---|---|
| 1 | 250 | 0.0499 | 35.8262 |
| 2 | 252.0 | 0.0500 | 30.0008 |
| 3 | 252.00 | 0.0500 | 29.9999 |
| 4 | 252.000 | 0.0500 | 30.0000 |

(C)

| | | | |
|---|---|---|---|
| 1 | 455 | 0.0031 | 34.1668 |
| 2 | 457.0 | 0.0030 | 25.6719 |
| 3 | 457.25 | 0.0030 | 24.9416 |
| 4 | 457.23 | 0.0030 | 25.0000 |

The “hybrid” scheme is a combination of the sparsity and the catch-an-pinpoint schemes disclosed above. In the hybrid scheme, first, the fundamental frequency is sought by the catch-and-pinpoint scheme since, at the first step, the object of interest is finding the fundamental frequency. Here, the first iteration of catch-and-pinpoint spans only the neighborhood of the fundamental frequency. Once the fundamental frequency is detected, the existence of any harmonic frequency is tested by investigating whether or not its corresponding signal vector is orthogonal to the noise vector.

### EXPERIMENTAL RESULTS

The following provides experimental data to compare the speed and accuracy of the sparsity (heuristic), catch-and-pinpoint, and hybrid schemes to that of the original S-LMS method. The dynamic behavior of the methods is also provided using different time-varying frequency patterns. Further, field data are used for performance verification.

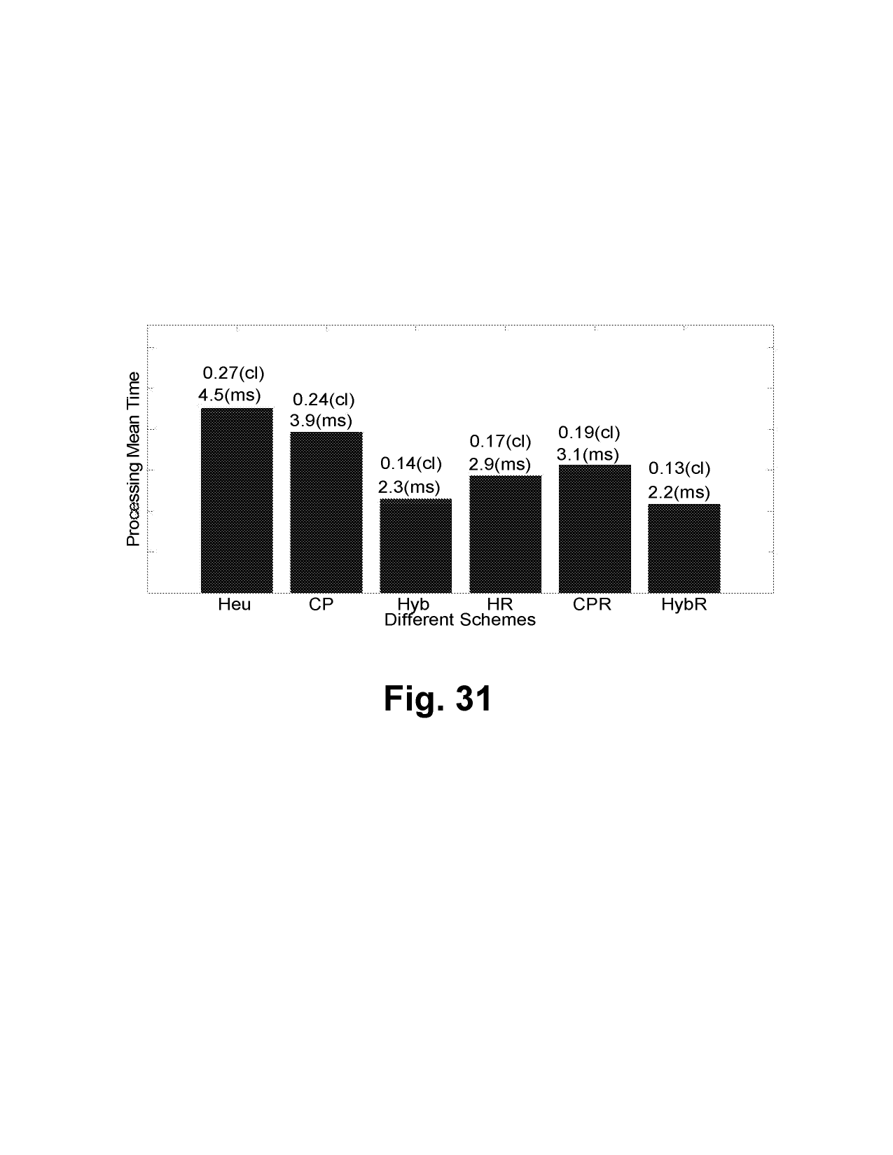

The following schemes have been implemented and tested. FIG. 31 shows the result of mean processing times for different schemes of implementation:
Heu: Heuristic (sparsity) scheme
CP: Catch-and-pinpoint scheme
Hyb: Hybrid
HR, CPR, and HybR: “Real” counterparts of Heu, CP and Hyb, respectively, with real-valued construction of the subspace function H(f).

In FIG. 31, the mean processing times for the heuristic (sparsity), catch-and-pinpoint, and hybrid schemes above are provided in milliseconds (ms) and also in cycles (cl). The S-LMS mean processing time is not shown in FIG. 31, since the mean processing time of the original S-LMS method (about 371 ms or, equivalently, 22.24 cycles) is, by far, larger than that of each of the heuristic (sparsity), catch-and-pinpoint, and hybrid schemes.

As FIG. 31 shows, the heuristic (sparsity) (Heu) scheme is the most time-consuming of the above schemes, with a mean processing time of 4.5 ms or, equivalently, 0.27 cycles. The best scheme, in terms of mean processing speed, is the real-implemented hybrid scheme (HybR), with a mean processing time of 2.2 ms or 0.13 cycles.

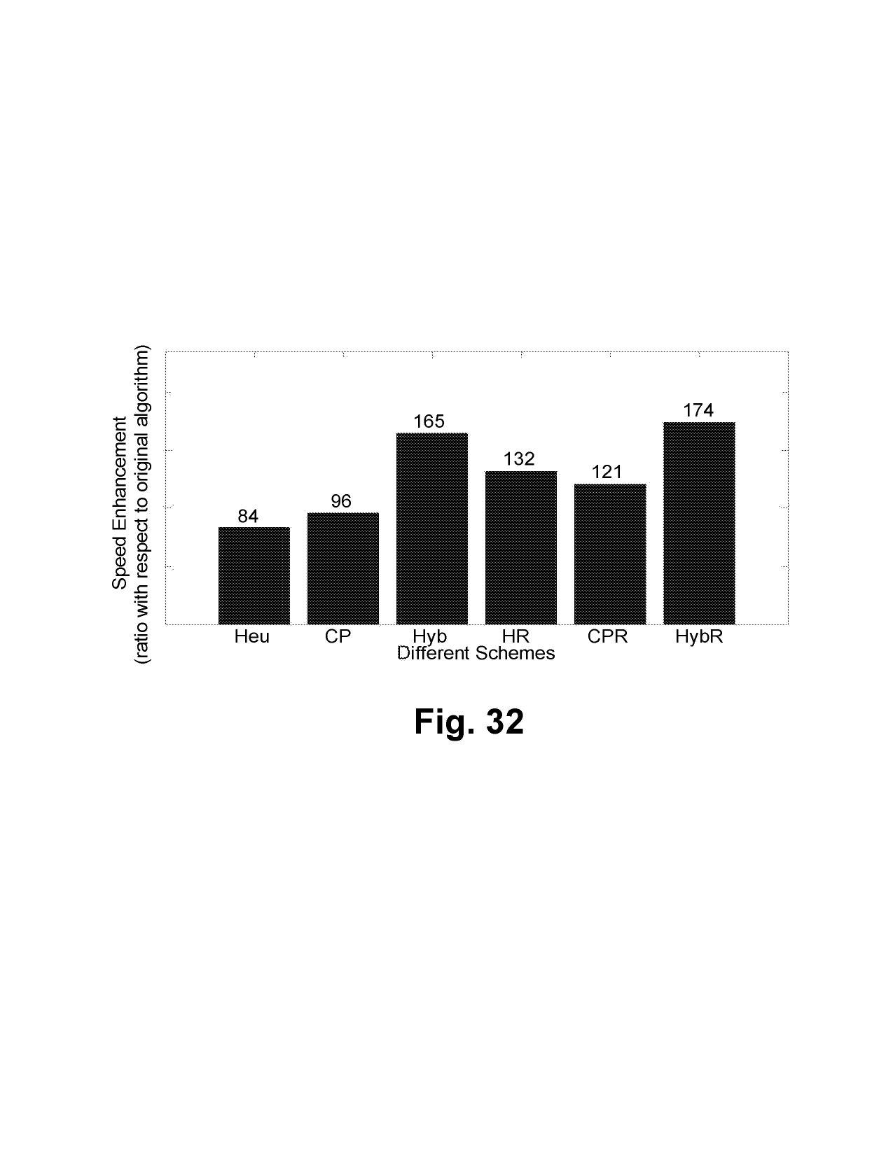

FIG. 32 shows the ratio of speed enhancement of each of the heuristic (sparsity) (Heu), catch-and-pinpoint (CP), and hybrid (Hyb) schemes as compared with the original S-LMS method. As illustrated in FIG. 32, the heuristic (sparsity) (Heu) scheme provides 84 times increase, and catch-and-pinpoint (CP) provides 96 times increase. The hybrid scheme using only real values (HybR) provides a 174 times increase as compared with the original S-LMS method.

The above results are obtained for a sampling rate of 3840 (N=64). If higher order harmonics are of interest, the sampling rate should be increased. This would increase the computational burden. In the original S-LMS method, the major burden is in constructing the subspace function and searching for its minima. For example, while the Org for N=64 takes about 371 ms, the calculation of the autocorrelation matrix and its eigenvalues and eigenvectors takes only 1.3 ms, which is negligible compared to the whole processing time. Since the above enhancement schemes (heuristic, catch-and-pinpoint, and hybrid) reduce the computational burden dramatically, for these schemes the computational load of the autocorrelation matrix calculation is no longer negligible. However, the final processing time for enhanced versions of the method will still be in the range of several milliseconds. For example, simulations for N=140 or a sampling rate of 8.4 kHz showed that Org mean processing time becomes 2634 ms while the calculation of eigenvalues and eigenvectors becomes 7.8 ms. As reported above, these values for N=64 were 371 ms and 1.3 ms, respectively. The processing time for HybR, for example, will increase from 2.2 ms (for N=64) to 9.8 ms (for N=140).

The accuracy of the heuristic (sparsity), catch-and-pinpoint, and hybrid schemes in terms of frequency, phase and amplitude are provided below. First, the accuracy of the various schemes is compared using the noise-free signal. Then, noisy signals are used for accuracy assessment. The test signal is composed of the fundamental component, 5^{th}, 7^{th}, 11^{th}, and 13^{th} harmonics and one interharmonics component. The mathematical expression of the test signal is in equation (16):

$$x ( t ) = {\sum }_{k = 1}^{6} {A}_{k} cos ( 2 π {f}_{k} t ) \qquad ( 16 )$$

where

A=[1, 0.05, 0.05, 0.04, 0.04, 0.02]

f=[f_{fund},5f_{fund}, 7f_{fund},11f_{fund},13f_{fund},457], f_{fund}=60.1

The amplitudes are adopted in accordance with reference to a statement that for the AEP 12.47/7.2-kV distribution system in the late 80s, the minimum voltage distortion is 1%, and may possibly exceed 5% for short terms.

The error indices are the absolute error for frequency and phase, and relative error for amplitude. Errors of phase are in degrees. Mathematically, these indices are expressed as follows in the following equations (17):

$${e}_{f} = \vert {f}_{estimated} - {f}_{exact} \vert \\ {e}_{φ} = \vert {φ}_{estimated} - {φ}_{exact} \vert ( in degree ) \\ {ɛ}_{A } \% = 100 \vert \frac{{A}_{estimated} - {A}_{exact}}{{A}_{exact}} \vert \qquad ( 17 )$$

Table VIII shows the simulation result for the noise-free signal.

TABLE VIII
Signal Parameters and Measurement Results in the Noise-Free Environment

| | Fundamental | | | 5^{th} Harmonic | | | 7^{th} Harmonic | | | 11^{th} Harmonic | | | 13^{th} Harmonic | | | Interharmonic | | |
|---|---|---|---|---|---|---|---|---|---|---|---|---|---|---|---|---|---|---|
| | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} |
| Org | 0 | 0 | 0 | 0 | 0 | 0 | 0 | 0 | 0 | 0 | 0 | 0 | 0 | 0 | 0 | 0 | 0 | 0 |
| Heu | 0 | 0 | 0.01 | 0 | 0.7 | 2.05 | 0 | 3.9 | 10.93 | 0 | 2.6 | 2.67 | 0 | 2.0 | 1.75 | — | — | — |
| CP | 0 | 0 | 0 | 0 | 0 | 0 | 0 | 0 | 0 | 0 | 0 | 0 | 0 | 0 | 0 | 0 | 0 | 0 |
| Hyb | 0 | 0 | 0.01 | 0 | 0.7 | 2.05 | 0 | 3.9 | 10.93 | 0 | 2.6 | 2.67 | 0 | 2.0 | 1.75 | — | — | — |
| HeuR | 0 | 0 | 0.01 | 0 | 0.7 | 2.05 | 0 | 3.9 | 10.93 | 0 | 2.6 | 2.67 | 0 | 2.0 | 1.75 | — | — | — |
| CPR | 0 | 0.03 | 0 | 0 | 0.9 | 0.1 | 0 | 2.9 | 0.6 | 0 | 0.3 | 0.3 | — | — | — | 0 | 0.3 | 5.5 |
| HybR | 0 | 0 | 0.01 | 0 | 0.7 | 2.05 | 0 | 3.9 | 10.93 | 0 | 2.6 | 2.67 | 0 | 2.0 | 1.75 | — | — | — |

In Table VIII, the data indicate that:
Org and CP provide the same results;
Org and CP detect all existing tones - the estimated frequencies and phasors are perfect;
CPR fails to find the 13^{th} harmonic component;
Heu, Hyb, HeuR, and HybR (heuristic-based methods) detect all harmonic components - the estimated frequencies are perfect, but the estimated phasors are not;
Heuristic-based methods introduce 0.7% amplitude error and about 2° error in phase for the 5^{th} harmonic; and
Heuristic-based methods provide better accuracy in estimating the fundamental and harmonic frequencies than Org and CP.

In this test case, the neglect of interharmonics in the heuristic-based methods (i.e., in Heu, Hyb, HeuR, and HybR) causes error in the estimation harmonic phasors, despite the fact that the method has estimated the frequency of the harmonic components perfectly. The reason is because the amplitude of the interharmonic is comparable to that of the harmonic components and the energy of this missing significant interharmonic is distributed to other signal phasors. Simulations showed (not included herein) that when the level of the interharmonic is negligible compared to that of harmonics, the results of heuristic-based methods converge to that of the original. Therefore, while the heuristic-based methods can be used for frequency and harmonic estimation even in the presence of high amplitude interharmonics, the heuristic-based methods can be used for harmonic amplitude and phase estimation when the interharmonic components are negligible compared to the harmonic components. In summary:
Heu, Hyb, HeuR and HybR can be used for fundamental and harmonic frequency estimation even when the interharmonic components are comparable to harmonic components; and
Heu, Hyb, HeuR and HybR can be used for fundamental and harmonic amplitude and angle estimation when the interharmonic components are negligible.

Table IX shows the results for SNR of 50 dB.

TABLE IX
Signal Parameters and Measurement Results in the Noisy Environment (SNR: 50 dB)

| | Fundamental | | | 5^{th} Harmonic | | | 7^{th} Harmonic | | | 11^{th} Harmonic | | | 13^{th} Harmonic | | | Interharmonic | | |
|---|---|---|---|---|---|---|---|---|---|---|---|---|---|---|---|---|---|---|
| | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} |
| Org | 0.01 | 0.01 | 0.10 | 0.28 | 0.39 | 2.35 | 0.29 | 3.65 | 3.49 | 0.17 | 1.59 | 0.54 | 0.3 | 0.27 | 1.28 | 1.83 | 12.24 | 8.74 |
| Heu | 0.01 | 0.01 | 0.12 | 0.05 | 0.66 | 4.01 | 0.07 | 2.40 | 11.16 | 0.11 | 4.95 | 2.61 | 0.13 | 1.83 | 1.95 | — | — | — |
| CP | 0.01 | 0.01 | 0.10 | 0.28 | 0.39 | 2.35 | 0.29 | 3.65 | 3.49 | 0.17 | 1.59 | 0.54 | 0.3 | 0.27 | 1.28 | 1.83 | 12.24 | 8.74 |
| Hyb | 0.01 | 0.01 | 0.12 | 0.05 | 0.66 | 4.01 | 0.07 | 2.40 | 11.16 | 0.11 | 4.95 | 2.61 | 0.13 | 1.83 | 1.95 | — | — | — |
| HeuR | 0.01 | 0.01 | 0.12 | 0.05 | 0.66 | 4.01 | 0.07 | 2.40 | 11.16 | 0.11 | 4.95 | 2.61 | 0.13 | 1.83 | 1.95 | — | — | — |
| CPR | 0.01 | 0.01 | 0.12 | 0.29 | 0.96 | 4.66 | 0.51 | 2.64 | 9.86 | 0.04 | 5.21 | 2.94 | — | — | — | — | — | — |
| HybR | 0.01 | 0.01 | 0.12 | 0.05 | 0.66 | 4.01 | 0.07 | 2.40 | 11.16 | 0.11 | 4.95 | 2.61 | 0.13 | 1.83 | 1.95 | — | — | — |

From the data provided in Table IX, the following observations can be made:
Org and CP detect all existing tones and provide identical results;
Heu, Hyb, HeuR and HybR (heuristic-based methods) detect all harmonic components and provide the same results;
For Org (or CP), the highest error in frequency estimation of harmonics is 0.29 Hz, but for the heuristic-based methods, the highest error is 0.13 Hz;
Fundamental phasor estimations for all methods are nearly the same, with 0.01% error in amplitude and 0.1° in phase;
Org and CP introduces 0.39% amplitude error and about 2.4° error in phase for the 5^{th} harmonic; and
Heuristic-based methods introduce about 0.7% amplitude error and about 4° error in phase for the 5^{th} harmonic.

Table X provides the results of simulation for SNR of 30 dB.

TABLE X
Signal Parameters and Measurement Results in the Noisy Environment (SNR: 30 dB)

| | Fundamental | | | 5^{th} Harmonic | | | 7^{th} Harmonic | | | 11^{th} Harmonic | | | 13^{th} Harmonic | | | Interharmonic | | |
|---|---|---|---|---|---|---|---|---|---|---|---|---|---|---|---|---|---|---|
| | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} | e_{f} | ε_{A} % | e_{φ} |
| Org | 0.07 | 0.04 | 0.97 | 2.10 | 4.04 | 24.06 | 2.84 | 8.98 | 6.22 | 0.73 | 53.62 | 8.05 | 3.45 | 4.65 | 23.94 | — | — | — |
| Heu | 0.07 | 0.11 | 0.97 | 0.33 | 3.65 | 20.56 | 0.46 | 11.04 | 12.40 | 0.72 | 26.53 | 2.68 | 0.85 | 0.59 | 5.39 | — | — | — |
| CP | 0.07 | 0.06 | 0.97 | 2.10 | 3.70 | 24.14 | 2.84 | 8.56 | 6.25 | 0.73 | 49.17 | 8.17 | 3.45 | 3.05 | 23.67 | — | — | — |
| Hyb | 0.07 | 0.11 | 0.97 | 0.33 | 3.65 | 20.56 | 0.46 | 11.04 | 12.40 | 0.72 | 26.53 | 2.68 | 0.85 | 0.59 | 5.39 | — | — | — |
| HeuR | 0.17 | 0.44 | 0.27 | 0.85 | 1.10 | 18.05 | 1.19 | 9.34 | 9.15 | 1.87 | 22.63 | 10.96 | 2.21 | 4.68 | 13.64 | — | — | — |
| CPR | 0.07 | 0.11 | 0.98 | 2.03 | 1.39 | 25.08 | 1.46 | 8.22 | 8.11 | 1.84 | 24.39 | 1.10 | — | — | — | — | — | — |
| HybR | 0.17 | 0.44 | 0.27 | 0.85 | 1.10 | 18.05 | 1.19 | 9.34 | 9.15 | 1.87 | 22.63 | 10.96 | 2.21 | 4.68 | 13.64 | — | — | — |

From the data provided in Table X, the following observations can be made:
Both Org and CP provide nearly identical results and detect all the harmonic components but fail to find the interharmonic;
Heu, Hyb, HeuR and HybR (heuristic-based methods) detect all harmonic components;
Heu or Hyb provide better results than HeuR or HybR; however, their superiority is not significant. For example, Hyb introduces 0.11% error in fundamental amplitude, while HybR introduces 0.44%;
For Org or CP, the highest error in frequency estimation of harmonics is 3.45 Hz, and for HeuR or HybR, the highest error is 2.21 Hz; and for Heu or Hyb, the highest error is 0.85 Hz;
Fundamental phasor estimations for all methods have nearly 0.1% error in amplitude and 1° in phase; and
Heuristic-based methods provide better accuracy in estimating the fundamental and harmonic frequencies than Org and CP.

In simulations, the threshold for filtering the spurious frequencies introduced by spurious minima of the subspace function was set at 0.01. Simulation for signals with an SNR of 30 dB showed that Org and CP introduce some spurious tones (not shown in Table X). These spurious tones are shown in Table XI, below:

TABLE XI
Spurious Tones Estimated by Org and
CP for Signals with an SNR of 30 dB

| Frequency | 6.1 f_{fund} | 11.4 f_{fund} | 20.6 f_{fund} | 21.1 f_{fund} | 21.6 f_{fund} |
|---|---|---|---|---|---|
| Amplitude | 0.013 | 0.023 | 0.021 | 0.025 | 0.013 |

In Table XI, the frequencies of the spurious tones have been shown as a multiple of the fundamental frequency (i.e., f=k f_{fund}). The methods have been used without prefiltering the samples.

In highly noisy environments, the original S-LMS method (Org) and the catch-and-pinpoint (CP) method need reinforcement by prefiltering. Yet another option is to use a wider data window in the LMS method. For example, simulations showed a data window of 2.5 cycles in the LMS section of the method filters these spurious tones.

Despite Org and CP, the heuristic-based methods do not introduce any spurious frequency even for highly noisy signals with an SNR of 30 dB and with an LMS data window of one cycle. Therefore, in addition to their faster speed, the heuristic-based methods provide more robust estimations as well.

Based on the results provided in Tables VII through XI, the following conclusions can be made:
The CPR scheme should be avoided since it cannot detect harmonics and interharmonics in a very noisy environment;
CP and Org provide the same result and they can detect interharmonics. Compared to Org and CP, heuristic-based methods (Heu, Hyb, HeuR and HybR) provide more resilience to noise. The preferred scheme, taking the computational burden also into account, is HybR in a moderately noisy signal (SNR of 50 dB) and Hyb in a highly noisy signal (SNR of 30 dB or less).

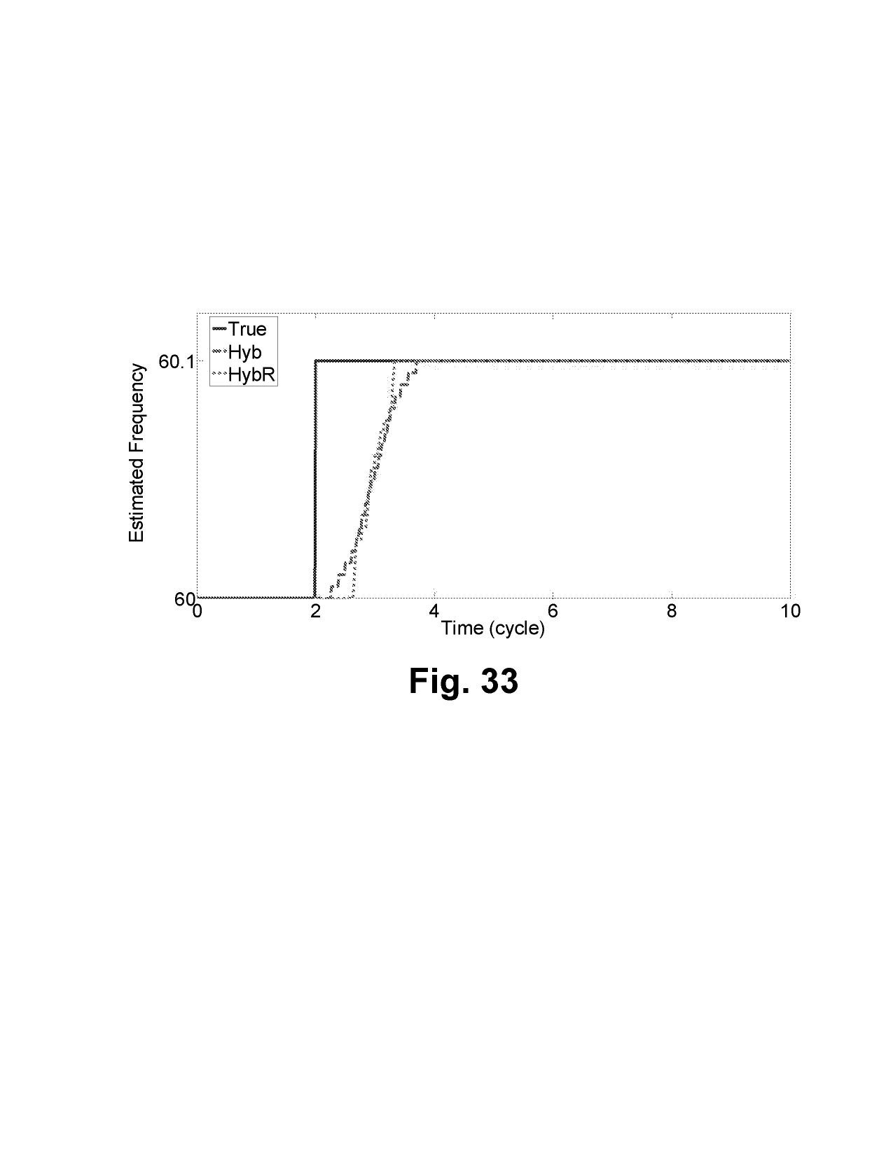

The dynamic behavior of the enhancement schemes above (heuristic (sparsity) (Heu), catch-and-pinpoint (CP), and hybrid (Hyb), as well as their “real” counterparts with real-valued construction of the subspace function H(f): HeuR, CPR and HybR, respectively) is also provided herein. Since the basis of each of the above schemes is based on the subspace method and calculation of the autocorrelation matrix, the expectation would be that each would have a similar dynamic response. However, simulations showed that Org, CP, Heu, and Hyb have the same dynamic response, and HeuR and HybR have a little different dynamic response. For this reason, only the dynamic responses of Hyb (representative of Org, CP, Heu, and Hyb) and HybR (representative of HeuR and HybR) are provided in FIGS. 33 through 35.

Case 1: Step Change in Frequency

The test signal is assumed to have a step change of 0.1 Hz in frequency. FIG. 33 illustrates the true frequency and estimated frequency using Hyb and HybR. The time is shown in cycles. Hyb starts to change 0.3 cycles after the step changes, HybR starts to change 0.6 cycles after the step change. Hyb reaches the steady state of 60.1 Hz in 1.7 cycles, and HybR reaches steady state in 1.4 cycles. In short, Hyb responds to the frequency step change earlier, but slower, than HybR does.

Case 2: Ramp Change in Frequency

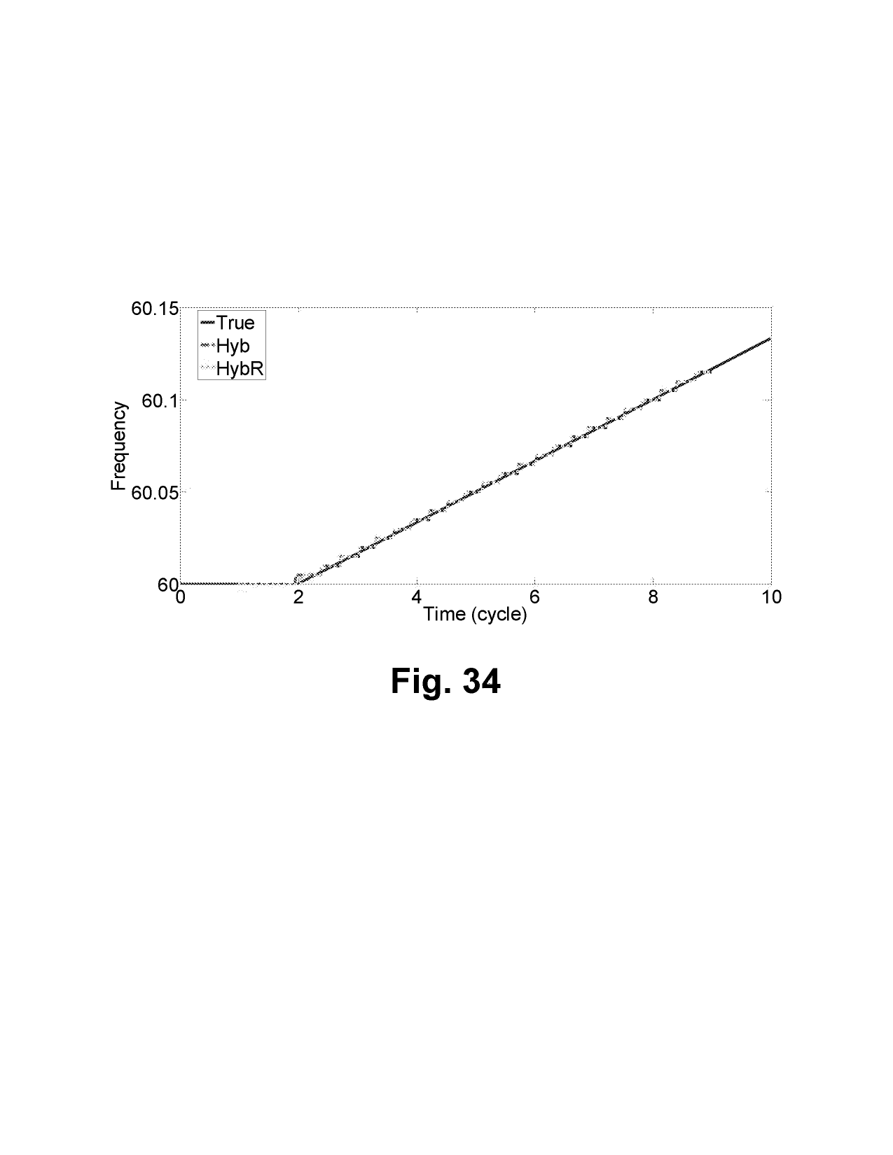

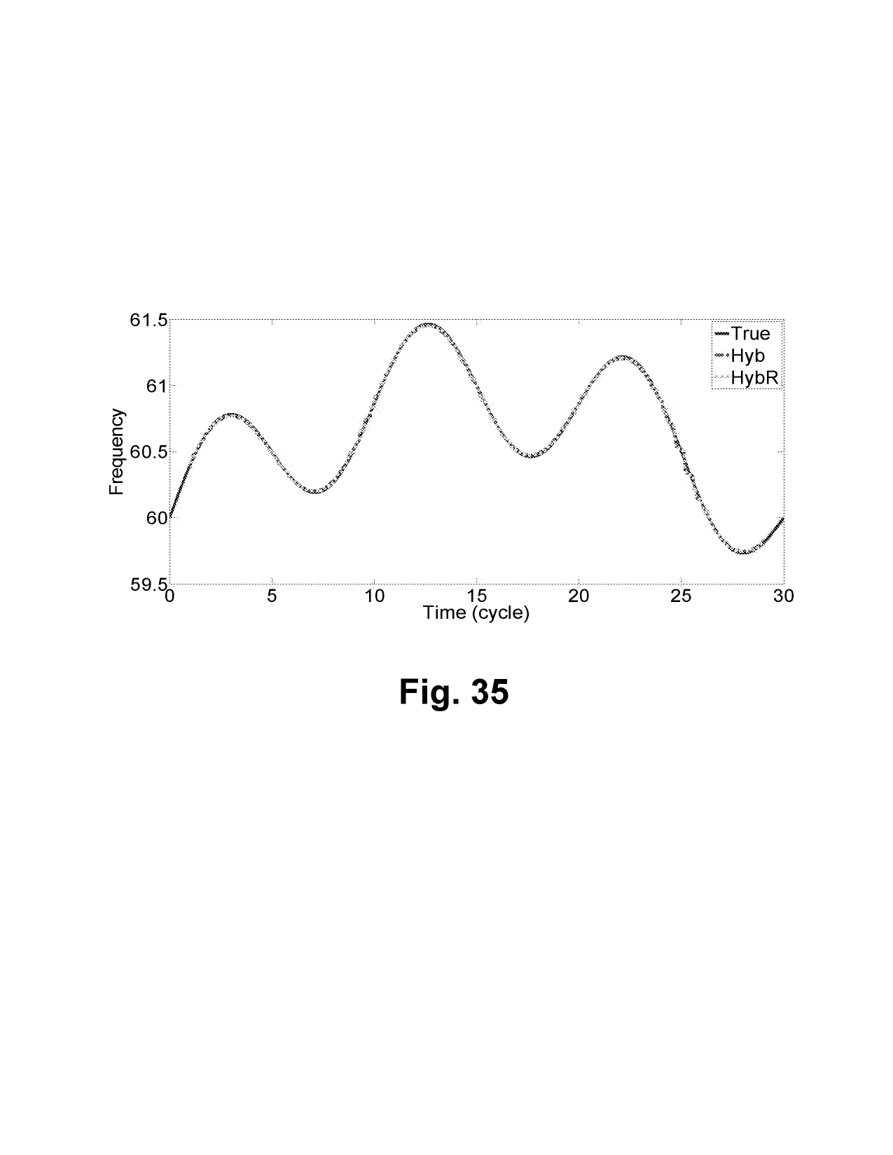

The test signal has a 1-Hz/second frequency change starting two cycles after the time reference. FIG. 34 illustrates the true frequency and estimated frequency using Hyb and HybR. Both track the frequency changes accurately. For better comparison with the true frequency, the estimated signal is shown with one cycle shift to the left in FIGS. 34 and 35.

Case 3: Modulation in Frequency

The test signal is the nominal frequency modulated by a 6-Hz subsynchronous frequency and a 1-Hz swing frequency. Mathematically, the test signal is provided in equation (18):

f=60+sin(2π6t)+0.5 sin(2π1t) (18)

FIG. 35 illustrates that test results from Hyb and HybR have negligible differences and both algorithms capture frequency swing accurately.

### Field Data

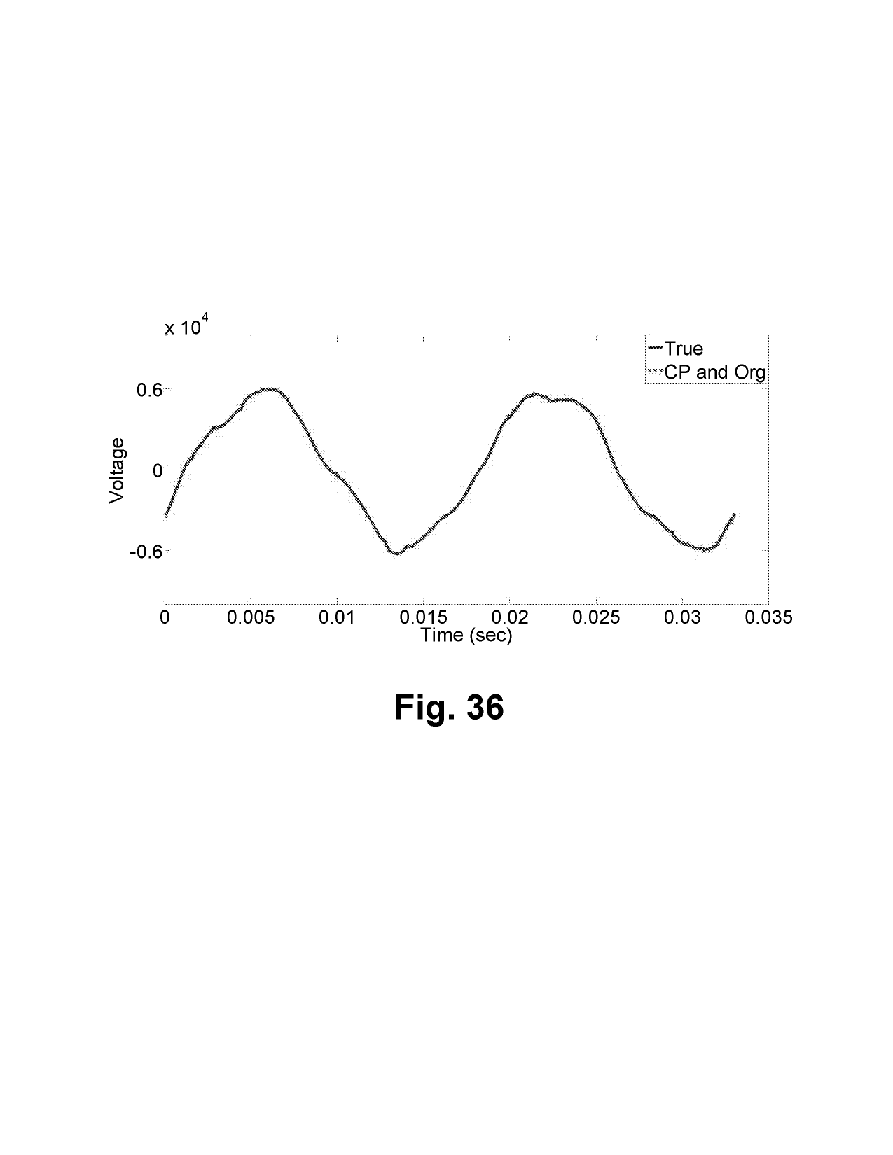

Field data are used to show the effectiveness of the S-LMS method. FIG. 36 illustrates a voltage signal recorded in a North American industrial plant with loads being majorly variable-frequency drive (VFD) motors. Most harmonic components were filtered out because of turning on harmonic filters. Therefore, a good candidate here is Org or CP, which can detect interharmonics. FIG. 36 illustrates the reconstructed signals using Org and CP, which are identical and match the real-field voltage signal very well.

Comparison with Other Methods

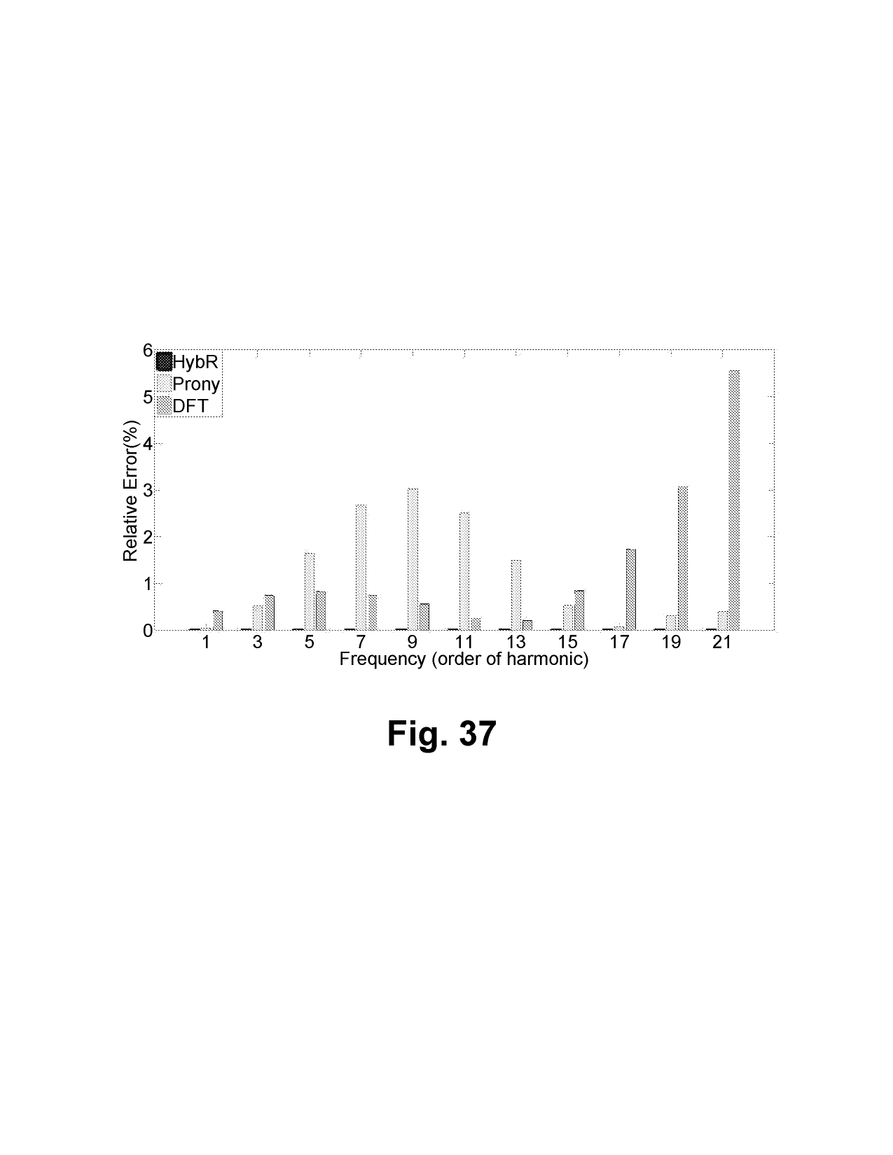

FIG. 37 illustrates a comparison of the S-LMS method of the present disclosure with two other methods, Prony and Discrete Fourier Transform (DFT). Since the different realizations of S-LMS provide similar estimations, for clarity in FIG. 37, the result is shown of one of the implementations, namely HybR. In all three methods (HybR, Prony, DFT), a data window of two cycles has been used. The test signal used is composed of the fundamental frequency6 and odd harmonics of order 3 to 21. The amplitudes of the harmonics are adopted as the reverse of the order of harmonic. Therefore, the test signal is as follows in equation (19):

$$x ( t ) = {\sum }_{k = 0}^{10} {A}_{k} cos ( 2 π ( 2 k + 1 ) {f}_{fund} ) + w ( t ) \qquad ( 19 )$$

where

$${A}_{k} = \frac{1}{2 k + 1} ,$$

f_{fund} is the fundamental frequency, and w(t) is additive noise. The methods are compared with respect to their ability to estimate the amplitude of the fundamental and harmonic tones.

Simulations showed that, while HybR is resilient to both off-nominal conditions and noise, DFT is severely affected by off-nominal conditions and Prony is extremely sensitive to noise.

FIG. 37 illustrates the result of a test case where f_{fund} is 59.9 Hz and the signal is slightly noisy with an SNR of 80 dB. While the relative errors of HybR are still practically zero, Prony's error reaches about 3% (for the 9^{th} harmonic) and the DFT's error reaches about 6% (for the 21^{st} harmonic).

The present disclosure provides a Subspace-Least Mean Square (S-LMS) method for fundamental, harmonic, and interharmonic frequency and phasor measurements in power systems. S-LMS provides a high-resolution and highly accurate estimation of the fundamental frequency, harmonics, interharmonics, and their corresponding amplitudes and phases. S-LMS is highly resilient to noise.

In addition, the speed, accuracy, resilience, and/or robustness of the S-LMS method can be enhanced by each of three schemes: (1) heuristic/sparsity (to find harmonics), (2) catch-and-pinpoint (to find both harmonics and interharmonics), and (3) a hybrid of the heuristic/sparsity and catch-and-pinpoint schemes. By using both the real-valued and imaginary-valued components of the signal, each of the schemes (Heu, CP, and Hyb) increases the speed, resiliency, and robustness of the S-LMS method. Moreover, by focusing on just the real-valued component of the signal, each of the schemes (i.e., HeuR, CPR, and HybR) can further increase the speed as compared with the original S-LMS method.

It should be understood that the foregoing description is only illustrative of the present disclosure. Various alternatives and modifications can be devised by those skilled in the art without departing from the disclosure. Accordingly, the present disclosure is intended to embrace all such alternatives, modifications, and variances that fall within the scope of the disclosure.

What is claimed is:

1. A method for phasor, harmonic and interharmonic measurements for power system monitoring and control, comprising:
a subspace-least mean square (S-LMS) method comprising:
a subspace (S) method to measure a power system frequency; and
a least mean square (LMS) method to process a power signal in time-domain,
wherein S-LMS method achieves ultra-high frequency resolution for the harmonic and interharmonic measurement for the power system monitoring and control.

2. The method according to claim 1, wherein the subspace (S) method comprises stochastic signals modeled by a sum of random sinusoidal signals in background noise with known covariance function.

3. The method according to claim 1, wherein the power system further comprises a power system signal.

4. The method according to claim 3, wherein the power system signal is non-stationary and non-linear.

5. The method according to claim 4, wherein the power system signal x(n) has L spectral components and additive white Gaussian noise (AWGN) w(n) by the following equation:
$$x ( n ) = {\sum }_{i = 1}^{L} {A}_{i} {e}^{j n {ω}_{i}} + w ( n ) ,$$
where Aᵢ=|Aᵢ|e^{jφ}^{ᵢ}, |Aᵢ| is the amplitude, φᵢ is the phase angle of the corresponding component, and ωᵢ is the frequency of i^{th} component.

6. The method according to claim 3, wherein the S-LMS method achieves ultra-high resolution phasor estimation for the power system signal.

7. The method according to claim 1, wherein the power system signal has frequencies that are calculated by identifying the zeros of a frequency function constructed using an eigenvector corresponding to the smallest eigenvalue of an autocorrelation matrix.

8. The method according to claim 6, wherein the eigenvector corresponding to the smallest eigenvalue of the autocorrelation matrix is the minimum eigenvector that is used to create frequencies.

9. The method according to claim 6, wherein the length of the minimum eigenvector is an arbitrary number larger than the number of sinusoids in a test signal for computation of a spectrum.

10. The method according to claim 7, wherein the autocorrelation matrix of the power system signal x(n), Rₓ, is an N-by-N Hermitian matrix, and wherein the Rₓ is expressed in terms of its eigendecomposition by the equation:
$${R}_{x} = V Λ {V}^{H} = {\sum }_{i = 1}^{N} {λ}_{i} {v}_{i} {v}_{i}^{H} ,$$
where Λ=diag(λ₁, λ₂, . . . λₙ) contains eigenvalues of Rₓ in descending order; V=[v₁, v₂, . . . v_{N}] is the matrix of corresponding eigenvectors; and the matrix V is split into two matrices that are the N×L matrix of signal eigenvectors Vₛ=[v₁, v₂, . . . v_{L}] and N×(N−L) matrix of noise eigenvectors Vₙ=[v_{L+1}, v_{L+2}, . . . v_{N}].

11. The method according to claim 10, wherein eigenvector vₙ corresponding to the smallest eigenvalues is a noise eigenvector that is orthogonal to a signal subspace as v_{N}⊥Vₛ by the equation:
V_{N}^{T}Vₛ=0.

12. The method according to claim 11, wherein the signal subspace is spanned by Vₛ=[e₁, e₂, . . . e_{L}], where eᵢ=[1 e^{jω}ᵢ . . . e^{j(N-1)ω}ᵢ]^{T}, i=1, 2, . . . . L, ωᵢ corresponds to the frequencies in the equation
$$x ( n ) = {\sum }_{i = 1}^{L} {A}_{i} {e}^{j n {ω}_{i}} + w ( n ) ,$$
and T is the transpose of a matrix, to give the following equation:
$${\sum }_{k = 0}^{N - 1} {v}_{N} ( k ) {e}^{j k {ω}_{i}} = 0.$$

13. The method according to claim 12, wherein a generalized subspace function H(ω) is:
$$H ( ω ) = {\sum }_{k = 0}^{N - 1} {v}_{N} ( k ) {e}^{j k ω} .$$

14. The method according to claim 13, further comprising locating the zeros of H(ω) to identify the frequencies of the signal.

15. The method according to claim 14, wherein locating the zeros of H(ω) is implemented by the discretized form as the equation:
H(ω)=H(mΔω)=E₁ν_{N},
where
$${E}_{1} = [ \begin{matrix}1 & 1 & … & 1 \\ 1 & {e}^{j Δ ω} & … & {e}^{j ( N - 1 ) Δ ω} \\ ⋮ & ⋮ & … & ⋮ \\ 1 & {e}^{j m Δ ω} & … & {e}^{j m ( N - 1 ) Δ ω} \\ ⋮ & ⋮ & … & ⋮ \\ 1 & {e}^{j ( 2 π - Δ ω )} & … & {e}^{j ( N - 1 ) ( 2 π - Δ ω )}\end{matrix} ]$$
and where Δω is the step size in screening signal frequencies, and where the dimension of E₁ is inversely proportional to Δω.

16. The method according to claim 14, wherein locating the zeros of H(ω) is by searching for minimum peaks of H(ω) below a threshold h,
wherein H(ωᵢ+Δω) is the consecutive forward value and H(ωᵢ−Δω) is the consecutive backward value of H(ωᵢ); and wherein H(ωᵢ) is treated as zero and ωᵢ is picked as one of the frequencies of the harmonic and interharmonic components of the signal when H(ωᵢ)<h and H(ωᵢ)<H(ωᵢ±Δω).

17. The method according to claim 16, wherein threshold h is set to h=1 for localization of frequencies in the signal.

18. The method according to claim 15, wherein the value of Δω is set to Δω=2π×0.1/fₛ (rad), where fₛ is the sampling rate, to achieve accuracy and reduce computation burdens.

19. The method according to claim 16, further comprising constructing a matrix E₂ after all frequency values are identified:
$${E}_{2} = [ \begin{matrix}1 & 1 & … & 1 \\ {e}^{j {ω}_{1}} & {e}^{j {ω}_{2}} & … & {e}^{j {ω}_{L}} \\ ⋮ & & & \\ {e}^{j M {ω}_{1}} & {e}^{j M {ω}_{2}} & … & {e}^{j M {ω}_{L}}\end{matrix} ] ,$$
where M can be any value that is larger than L.

20. The method according to claim 17, further comprising a column vector of signal measurements Y, where Y=[x(1), x(2), . . . , x(M+1)]^{T} and E₂A=Y, where A=[A₁, A₂, . . . , A_{L}]^{T} and Aᵢ=|Aᵢ|^{ejΦ}^{ᵢ}.

21. The method according to claim 18, wherein matrix A carries information of amplitudes and phase angles of all harmonic and interharmonic components, including fundamental frequency component, and wherein matrix A is computed by the LMS method to give the equation:
A=(E₂^{H}E₂)⁻¹E₂^{H}Y.

22. The method according to claim 1, wherein the LMS method calculates amplitudes and phase angles of harmonic and interharmonic components, and wherein the calculation has inputs comprising computed frequencies and time domain measurements of the power signal.

23. The method according to claim 1, wherein the ultra-high frequency resolution is 0.2 Hz for a data window length of 1/30 second.

24. The method according to claim 1, wherein the S-LMS method achieves direct estimates of phasors, wherein the estimates comprise frequency, magnitude and phase angles for power system states that contain harmonics, interharmonics, and noise.

25. The method according to claim 1, wherein the S-LMS method achieves accurate estimates of any harmonics and interharmonics in noisy environments and/or in fast dynamic conditions with a data sampling window of 33.3 milliseconds (ms).

26. The method according to claim 1, wherein the S-LMS method achieves high frequency resolution.

27. The method according to claim 1, wherein the S-LMS method achieves enhanced noise tolerance.

28. The method according to claim 1, wherein the S-LMS method achieves enhanced performance under fundamental frequency deviations as compared with Discrete Fourier Transform (DFT) methods.

29. The method according to claim 1, wherein the S-LMS method further comprises a sampling frequency, wherein the sampling frequency is at least twice the highest frequency of interest.

30. The method according to claim 29, wherein the sampling frequency is 3840 Hz to capture components within a frequency range of 0 to 1920 Hz for accurate estimation of phasors and higher frequency components up to the 31^{st} harmonic and corresponding interharmonics.

31. The method according to claim 1, wherein the subspace (S) method avoids counting the number of sinusoids in the test signal for computation of a spectrum, thereby reducing computational burden, increasing accuracy, and achieving highly stable performance even in very noisy environments.

32. The method according to claim 1, wherein the accurate phasor, harmonic, and interharmonic measurements of power systems is used for an application selected from the group consisting of power quality analyzers, synchronized phasor measurement, situational awareness, dynamic equivalencing, smart meters, and any combinations thereof.

33. The method according to claim 1, wherein the S-LMS method is a parameter estimation method for sinusoidal models for analyzing, modeling and manipulating time-series selected from the group consisting of speech and audio signal, radar and sonar signals, estimation of delay and Doppler profiles from Frequency Modulated Continuous Wave (FMCW) channel data with in-band interference, interharmonics in electric power systems and submarine systems, speech sinusoidal models, multi-path communication channels, helicopter recognition, and any combinations thereof.

34. The method according to claim 1, further comprising:
a scheme selected from the group consisting of: sparsity; catch-and-pinpoint; and a hybrid of sparsity and catch-and-pinpoint,
wherein the scheme increases the speed of the S-LMS method.

35. The method according to claim 34, wherein the scheme only uses a real-value component of a complex-valued vector to locate signal frequencies to further increase the speed of the S-LMS method.
